(19) United States
(12) Patent Application Publication
(10) Pub. No.: US 2024/0186158 A1
(43) Pub. Date: Jun. 6, 2024

(54) TRANSFER MODULE AND TRANSFER METHOD

(71) Applicant: Tokyo Electron Limited, Tokyo (JP)

(72) Inventors: Norihiko AMIKURA, Miyagi (JP); Makoto SAEGUSA, Miyagi (JP); Toshiaki TOYOMAKI, Miyagi (JP); Seiichi KAISE, Miyagi (JP); Masatomo KITA, Miyagi (JP)

(73) Assignee: Tokyo Electron Limited, Tokyo (JP)

(21) Appl. No.: 18/525,930

(22) Filed: Dec. 1, 2023

(30) Foreign Application Priority Data
Dec. 1, 2022 (JP) 2022-192609

(51) Int. Cl. H01L 21/67; H01L 21/677

(52) U.S. Cl. CPC H01L 21/67196; H01L 21/67184; H01L 21/67742

(57) ABSTRACT

The present disclosure provides a transfer module, comprising: a first transfer chamber; a second transfer chamber, the second transfer chamber capable of accommodating a container accommodating a plurality of objects; and an opening/closing door configured to partition the first transfer chamber and the second transfer chamber, wherein the first transfer chamber has an accommodation portion configured to accommodate the object to be carried into the second transfer chamber, and the container accommodating the plurality of objects is carried into the second transfer chamber, the plurality of objects are transferred from the container to the accommodation portion in the first transfer chamber, the object is transferred from the accommodation portion into the vacuum transfer module, and the object carried out from the vacuum transfer module is transferred into the container without passing through the accommodation portion.

### CROSS-REFERENCE TO RELATED APPLICATION

This application claims priority to Japanese Patent Application No. 2022-192609 filed on Dec. 1, 2022, the entire contents of which are incorporated herein by reference.

### TECHNICAL FIELD

Various aspects and embodiments of the present disclosure relate to a transfer module and a transfer method.

### BACKGROUND

Japanese Laid-open Patent Publication No. 2021-141136 discloses that “The substrate processing system 1 includes a main body 10 and a control device 100 that controls the main body 10. The main body 10 includes a vacuum transfer module 11, a plurality of substrate processing modules 12, a plurality of load lock modules 13, a plurality of storage modules 14, and a substrate aligner module 15. Further, the main body 10 includes an edge ring (ER) aligner module 16, an atmospheric transfer module 17, and a plurality of load ports 18.”

### SUMMARY

The present disclosure provides a transfer module and a transfer method capable of reducing an installation area of a substrate processing system.

Specifically, the present disclosure provides a transfer module, comprising: a first transfer chamber connected to a vacuum transfer module and configured to be maintained at a low pressure lower than atmospheric pressure; a second transfer chamber provided on a second sidewall other than a sidewall opposite to a first sidewall to which the vacuum transfer module is connected in the first transfer chamber or in an upper portion of the first transfer chamber, the second transfer chamber capable of accommodating a container accommodating a plurality of objects to be transferred and being configured to be able to switch an internal pressure between the atmospheric pressure and the low pressure; and an opening/closing door configured to partition the first transfer chamber and the second transfer chamber, wherein the first transfer chamber has an accommodation portion configured to accommodate the object to be transferred, and the container accommodating the plurality of objects to be transferred is carried into the second transfer chamber, the opening/closing door is controlled to communicate a space in the first transfer chamber and a space in the second transfer chamber after a pressure in the second transfer chamber is switched from the atmospheric pressure to the low pressure, the plurality of objects to be transferred are transferred from the container to the accommodation portion in the first transfer chamber, the object to be transferred is transferred from the accommodation portion into the vacuum transfer module, and the object to be transferred carried out from the vacuum transfer module is transferred into the container without passing through the accommodation portion.

### BRIEF DESCRIPTION OF THE DRAWINGS

FIG. 1 is a schematic plan view illustrating an example of a substrate processing system in a first embodiment.

FIG. 2 is a schematic cross-sectional view illustrating an example of a cross-section A-A of the substrate processing system illustrated in FIG. 1.

FIG. 3 is a schematic cross-sectional view illustrating an example of a cross-section B-B of the substrate processing system illustrated in FIG. 2.

FIG. 4 is a flowchart illustrating an example of a transfer method of a substrate in the first embodiment.

FIG. 5 is a diagram illustrating an example of a transfer process of a substrate in the first embodiment.

FIG. 6 is an enlarged cross-sectional view illustrating an example of a connecting portion between a stage and a container.

FIG. 7 is an enlarged cross-sectional view illustrating an example of a connecting portion between a stage and a container.

FIG. 8 is a diagram illustrating an example of a transfer process of a substrate in the first embodiment.

FIG. 9 is a diagram illustrating an example of a transfer process of a substrate in the first embodiment.

FIG. 10 is an enlarged cross-sectional view illustrating an example of a connecting portion between a stage and a container.

FIG. 11 is an enlarged cross-sectional view illustrating an example of a connecting portion among a stage, an EFEM, and a housing.

FIG. 12 is a diagram illustrating an example of a transfer process of a substrate in the first embodiment.

FIG. 13 is a diagram illustrating an example of a transfer process of a substrate in the first embodiment.

FIG. 14 is a diagram illustrating an example of a transfer process of a substrate in the first embodiment.

FIG. 15 is a diagram illustrating an example of a transfer process of a substrate in the first embodiment.

FIG. 16 is a schematic plan view illustrating another example of a substrate processing system in the first embodiment.

FIG. 17 is a schematic cross-sectional view illustrating an example of the cross-section A-A of the substrate processing system illustrated in FIG. 16.

FIG. 18 is a schematic sectional view illustrating an example of the cross-section B-B of the substrate processing system illustrated in FIG. 17.

FIG. 19 is a schematic cross-sectional view illustrating another example of the cross section A-A of the substrate processing system illustrated in FIG. 16.

FIG. 20 is a schematic plan view illustrating an example of a substrate processing system in a second embodiment.

FIG. 21 is a schematic cross-sectional view illustrating an example of the cross-section A-A of the substrate processing system illustrated in FIG. 20.

FIG. 22 is a schematic cross-sectional view illustrating an example of the cross-section B-B of the substrate processing system illustrated in FIG. 21.

FIG. 23 is a schematic cross-sectional view illustrating an example of the cross-section C-C of the substrate processing system illustrated in FIG. 21.

FIG. 24 is a schematic cross-sectional view illustrating an example of the cross-section D-D of the substrate processing system illustrated in FIG. 21.

FIG. 25 is a flowchart illustrating an example of a transfer method of a substrate in the second embodiment.

FIG. 26 is a diagram illustrating an example of a transfer process of a substrate in the second embodiment.

FIG. 27 is a diagram illustrating an example of a transfer process of a substrate in the second embodiment.

FIG. 28 is a diagram illustrating an example of a transfer process of a substrate in the second embodiment.

FIG. 29 is a diagram illustrating an example of a transfer process of a substrate in the second embodiment.

FIG. 30 is a diagram illustrating an example of a transfer process of a substrate in the second embodiment.

FIG. 31 is a diagram illustrating an example of a transfer process of a substrate in the second embodiment.

FIG. 32 is a diagram illustrating an example of a transfer process of a substrate in the second embodiment.

FIG. 33 is a diagram illustrating an example of a transfer process of a substrate in the second embodiment.

FIG. 34 is a diagram illustrating an example of a transfer process of a substrate in the second embodiment.

FIG. 35 is a diagram illustrating an example of a transfer process of a substrate in the second embodiment.

### DETAILED DESCRIPTION

Hereinafter, embodiments of a transfer module and a transfer method will be described in detail with reference to the drawings. In addition, the described transfer module and transfer method are not limited to the following embodiments.

In order to increase the number of substrates that may be processed per unit time, it may be an option to increase the number of processing modules that process the substrates. However, as the number of processing modules increases, a substrate processing system, which includes a plurality of processing modules, becomes larger in size. When the size of system is increased, the the processing substrate installation area (footprint) of the substrate processing system in a facility such as a clean room is increased, which makes it difficult to dispose a plurality of substrate processing systems. For that reason, there is a demand for reducing the installation area of the substrate processing system.

Accordingly, the present disclosure provides a technique for reducing the installation area of the substrate processing system.

### First Embodiment

### (Configuration of the Substrate Processing System 1)

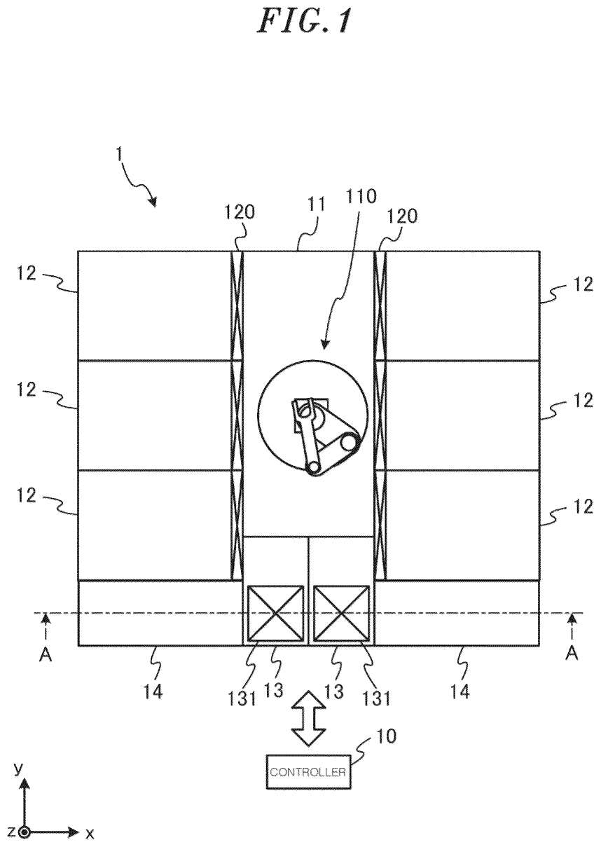

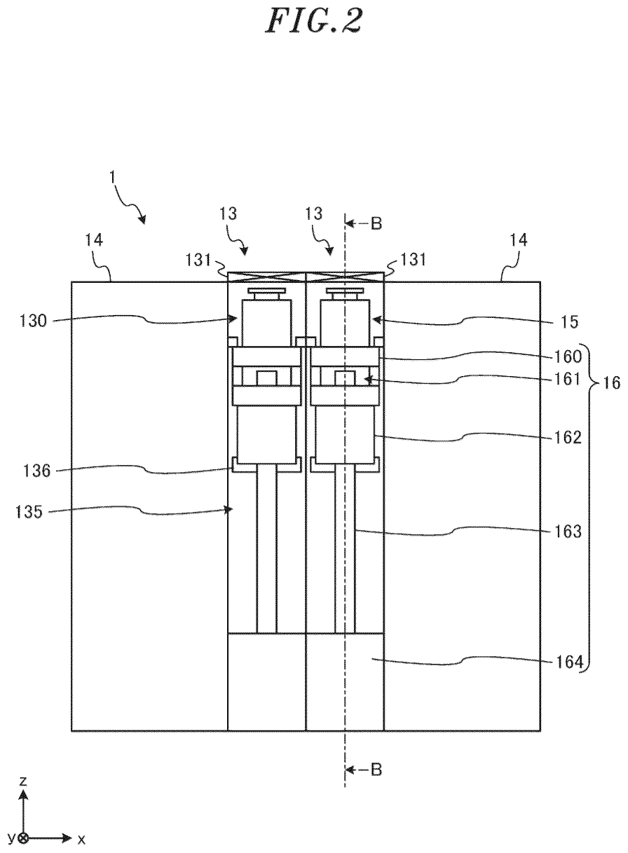

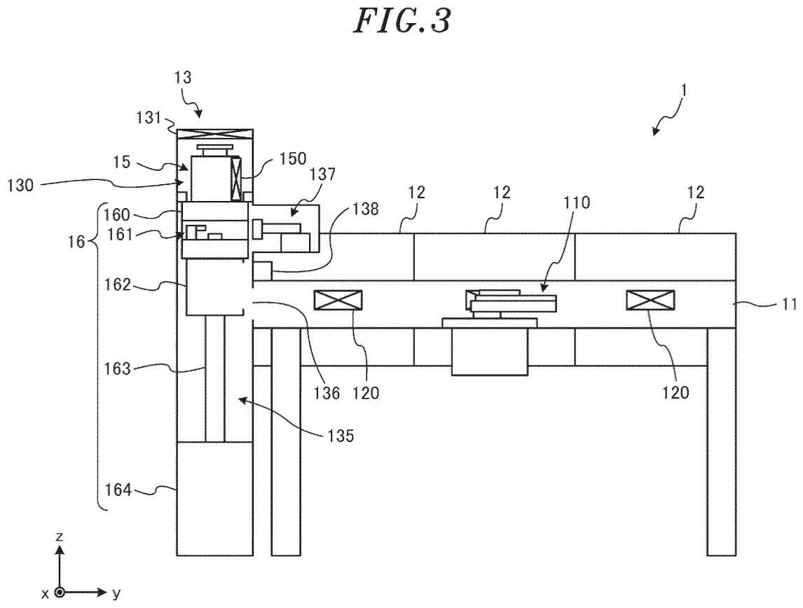

FIG. 1 is a plan view illustrating an example of a substrate processing system 1 in a first embodiment. FIG. 2 is a schematic cross-sectional view illustrating an example of a cross-section A-A of the substrate processing system 1 illustrated in FIG. 1. FIG. 3 is a schematic cross-sectional view illustrating an example of a cross-section B-B of the substrate processing system 1 illustrated in FIG. 2. In FIG. 1, for the sake of convenience, the internal components of some devices are illustrated as being visible. In addition, in FIG. 2, illustration of the internal configuration of a utility unit 14 is omitted.

For example, as illustrated in FIG. 1, the substrate processing system 1 includes a vacuum transfer module (VTM) 11, a plurality of processing modules (PM) 12, and a plurality of equipment front end modules (EFEM) 13. The EFEM 13 is an example of a transfer module. In the example of FIG. 1, the VTM 11 extends in a y-axis direction of FIG. 1, and the plurality of PMs 12 are disposed adjacent to the VTM 11 in an x-axis direction of FIG. 1. Further, in the example of FIG. 1, the plurality of EFEMs 13 are disposed adjacent to the VTM 11 in a y-axis direction of FIG. 1. Further, in the example of FIG. 1, a plurality of utility units 14 are disposed adjacent to the EFEM 13 in an x-axis direction of FIG. 1. Inside the utility unit 14, electrical wiring, gas piping, etc. are disposed. The utility unit 14 is an example of an equipment accommodation chamber.

The plurality of PMs 12 are connected to sidewalls of the VTM 11 via gate valves 120. Each PM 12 performs a process such as etching or film formation on a substrate W to be processed. The substrate W is an example of an object to be transferred. In addition, in the example of FIG. 1, six PMs 12 are connected to the VTM 11, but the number of PMs 12 connected to the VTM 11 may be more than six or less than six.

A transfer robot 110 is provided in the VTM 11. The transfer robot 110 transfers the substrate W between the PM 12 and the EFEM 13. The inside of the VTM 11 is maintained at a low pressure atmosphere lower than the atmospheric pressure.

The plurality of EFEMs 13 are connected to the other sidewalls of the VTM 11. In the example of FIG. 1, two EFEMs 13 are connected to the VTM 11, but the number of EFEMs 13 connected to the VTM 11 may be more than two or less than two.

For example, as illustrated in FIGS. 2 and 3, each EFEM 13 is provided with a first transfer chamber 135 and a second transfer chamber 130. The space within the first transfer chamber 135 communicates with the space within the VTM 11 through an opening 136, and is maintained at a low pressure lower than the atmospheric pressure. In addition, the first transfer chamber 135 may accommodate a container 15 that accommodates a plurality of substrates W. The container 15 is, for example, a FOUP (Front Opening Unified Pod). A gate valve 131 is provided in an upper portion of the second transfer chamber 130. The second transfer chamber 130 is provided in an upper portion of the first transfer chamber 135 and may accommodate the container 15. Further, the second transfer chamber 130 is configured to be able to switch the internal pressure between atmospheric pressure and a low pressure that is the same pressure as the pressure inside the first transfer chamber 135.

A moving mechanism 16 is provided within the first transfer chamber 135. The moving mechanism 16 includes a stage 160, an aligner module 161, an accommodation portion 162, a support portion 163, and a drive portion 164. The stage 160 partitions the second transfer chamber 130 and the first transfer chamber 135. Further, the stage 160 may have the container 15 mounted on its upper surface. The stage 160 is an example of an opening/closing door. An aligner module 161 adjusts a direction of the substrate W.

For example, as illustrated in FIG. 3, in the first transfer chamber 135, a cover attaching/detaching mechanism 137 for detaching and attaching a cover 150 of the container 15 is provided. Further, a sensor 138 is provided on the sidewall of the EFEM 13. The sensor 138 detects a location of the substrate W accommodated in the container 15 when the container 15 with the cover 150 detached passes through the first transfer chamber 135 near the sensor 138.

The aligner module 161 for adjusting the direction of the substrate W is provided below the stage 160. The accommodation portion 162 for temporarily holding the plurality of substrates W is provided below the stage 160. The stage 160, the aligner module 161, and the accommodation portion 162 are supported by the support portion 163. The drive portion 164 moves the support portion 163 in a vertical direction (z-axis direction in FIGS. 1 to 3). When the drive portion 164 moves the support portion 163 in a vertical direction, the stage 160, the aligner module 161, and the accommodation portion 162 integrally move in a vertical direction.

As described above, in this embodiment, the EFEM 13 is connected to the VTM 11, and no load lock module is provided between the VTM 11 and the EFEM 13. Accordingly, compared to a substrate processing system having a configuration in which the load lock module is provided between the VTM 11 and the EFEM 13, the installation area of the substrate processing system 1 may be reduced.

A controller 10 includes a memory, a processor, and an input/output interface. The memory stores data such as recipes, and programs. For example, the memory may include a random access memory (RAM), a read only memory (ROM), a hard disk drive (HDD), a solid state drive (SSD), or the like. The processor executes a program read from the memory to control each portion of the substrate processing system 1 through the input/output interface based on the data such as the recipe stored in the memory. For example, the processor may be a central processing unit (CPU) or a digital signal processor (DSP).

### [Transfer Method]

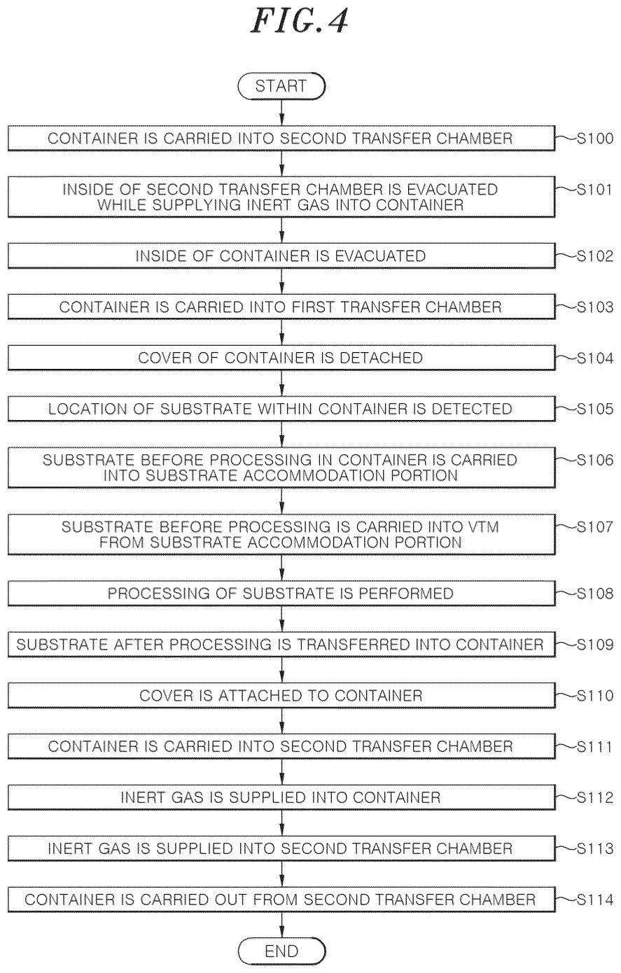

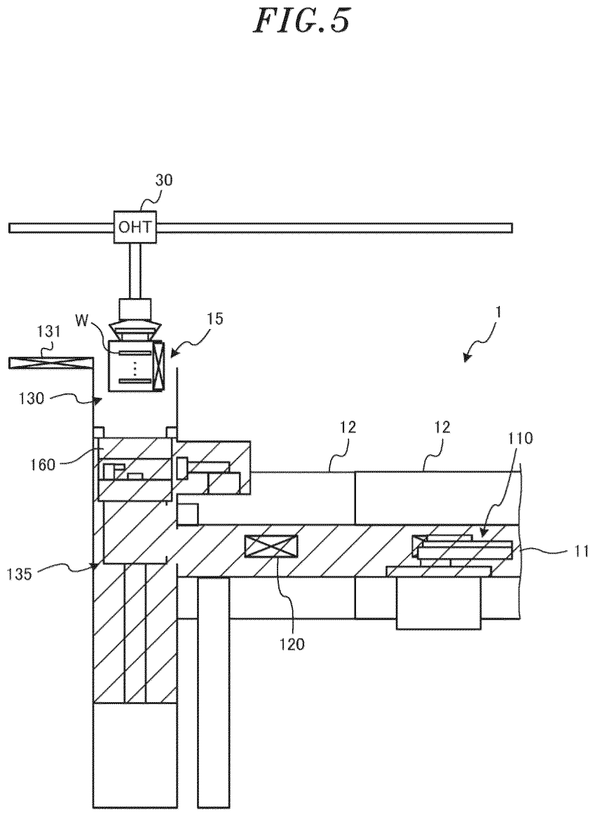

FIG. 4 is a flowchart illustrating an example of a transfer method of the substrate W in the first embodiment. Hereinafter, an example of the transfer method of the substrate W illustrated in FIG. 4 will be described below with reference to FIGS. 5 to 15. In addition, in FIGS. 5 to 15, a low pressure space is hatched to distinguish between the atmospheric pressure space and the low pressure space.

First, the container 15 accommodating the plurality of substrates W before processing is carried into the second transfer chamber 130 (S100). Step S100 is an example of process a). In step S100, for example, as illustrated in FIG. 5, the gate valve 131 is opened, and the container 15 accommodating the plurality of substrates W before processing is transferred by a transfer mechanism such as an Overhead Hoist Transport (OHT) 30 and is carried into the second transfer chamber 130. Then, the container 15 is mounted on the stage 160, and the gate valve 131 is closed.

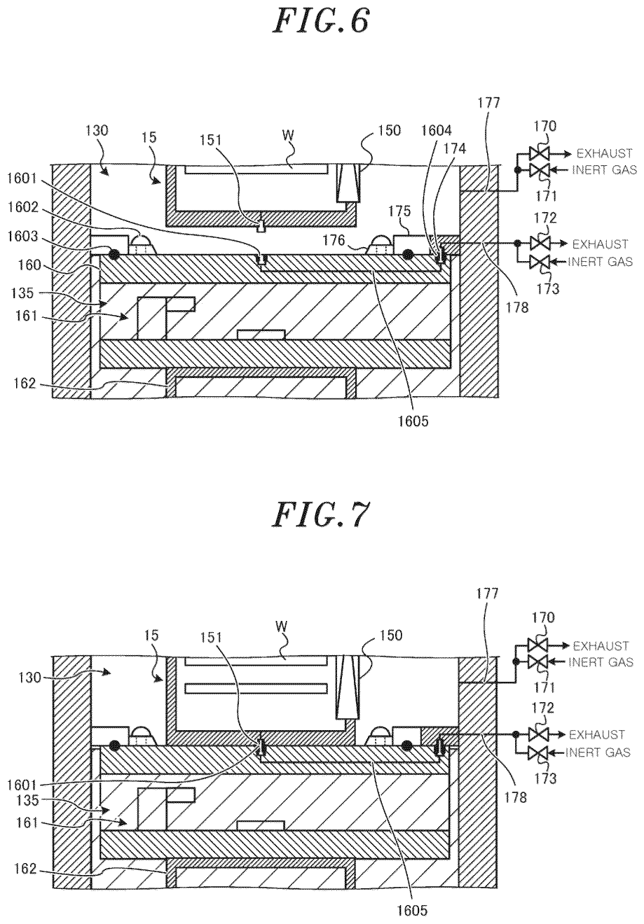

FIGS. 6 and 7 are enlarged cross-sectional views illustrating an example of a connecting portion between the stage 160 and the container 150. For example, as illustrated in FIG. 6, a connector 151 for connecting a gas pipe is provided in a lower portion of the container 15. A connector 1601 that fits into the connector 151 of the container 15 is provided on an upper surface of the stage 160. A connector 1604 is connected to the connector 1601 via a pipe 1605. A connector 174 is fitted into the connector 1604. The connector 174 is connected to a valve 172 and a valve 173 via a pipe 178.

For example, as illustrated in FIG. 7, when the container 15 is mounted on the stage 160, the connector 151 of the container 15 and the connector 1601 of the stage 160 are fitted. As a result, the gas in the container 15 may be exhausted by opening the valve 172, and an inert gas may be supplied into the container 15 by opening the valve 173.

Furthermore, a valve 170 and a valve 171 are connected to the space within the second transfer chamber 130 via a pipe 177. By opening the valve 170, the gas in the second transfer chamber 130 may be exhausted, and by opening the valve 171, an inert gas may be supplied into the second transfer chamber 130. The inert gas in this embodiment is, for example, nitrogen gas, rare gas, dry air, or the like.

Furthermore, a thick-tipped projection 1602 is provided on an upper surface of the stage 160. A drive portion 175 is provided on the sidewall of the second transfer chamber 130. A sealing member 1603 such as an O-ring is disposed between the drive portion 175 and the stage 160. The drive portion 175 moves a tapered cylinder 176 in a lateral direction. The drive portion 175 locks the stage 160 by inserting the cylinder 176 into the base of the projection 1602. By locking the stage 160, the space within the first transfer chamber 135 and the space within the second transfer chamber 130 are airtightly separated.

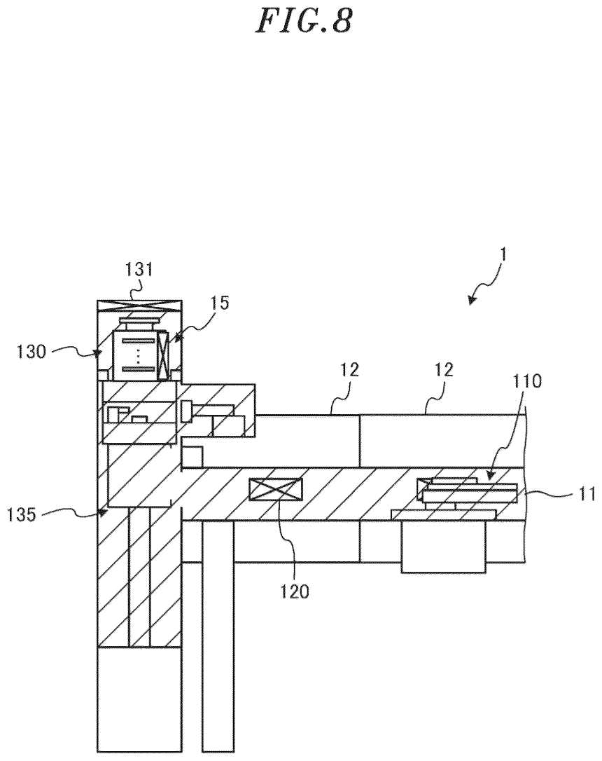

Returning to FIG. 4, the explanation will be continued. After the container 15 is carried into the second transfer chamber 130, the inside of the second transfer chamber 130 is evacuated while supplying an inert gas into the container 15 (S101). Step S101 is an example of process b). In step S101, an inert gas is supplied into the container 15 by opening the valve 173, and the gas in the second transfer chamber 130 is exhausted by opening the valve 170. As a result, for example, as illustrated in FIG. 8, the pressure inside the second transfer chamber 130 may be set to the same low pressure as the pressure inside the first transfer chamber 135 while maintaining the inside of the container 15 at atmospheric pressure.

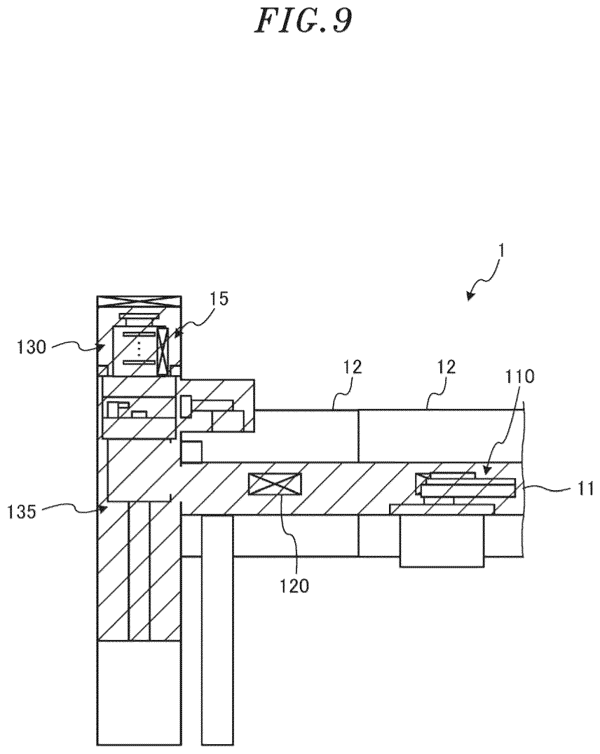

Next, the inside of the container 15 is evacuated (S102). In step S102, the gas in the container 15 is exhausted by closing the valve 173 and opening the valve 172. As a result, for example, as illustrated in FIG. 9, the pressure in the container 15 and the pressure in the second transfer chamber 130 may be set to the same low pressure as the pressure in the first transfer chamber 135. As such, by lowering the pressure in the second transfer chamber 130 earlier than in the container 15, it is possible to prevent particles and the like in the second transfer chamber 130 from entering the container 15.

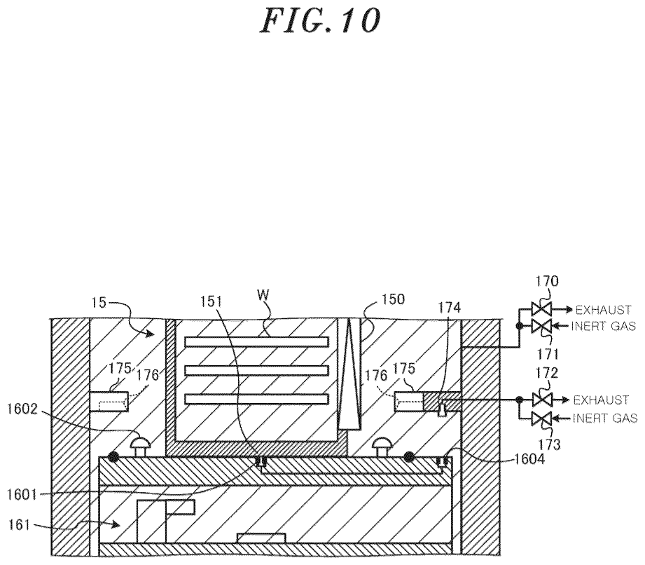

Next, the container 15 is carried into the first transfer chamber 135 (S103). Step S103 is an example of process c). In step S103, for example, as illustrated in FIG. 10, the cylinder 176 is retracted from the base of the projection 1602 by the drive portion 175, and the stage 160 is unlocked. Then, the stage 160, the aligner module 161, and the accommodation portion 162 are lowered by driving the drive portion 164, and the container 15 on the stage 160 is carried into the first transfer chamber 135.

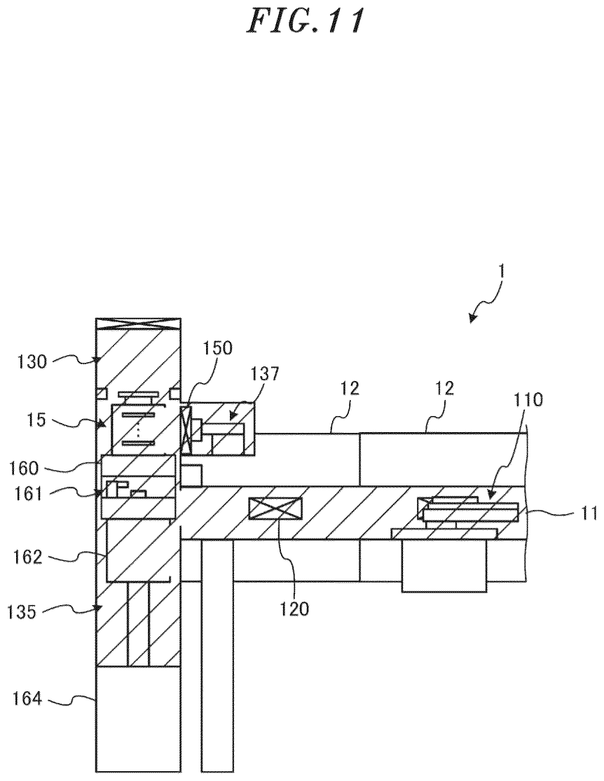

Next, the cover 150 of the container 15 is detached (S104). In step S104, for example, as illustrated in FIG. 11, the cover 150 of the container 15 is detached by the cover attachment/detachment mechanism 137.

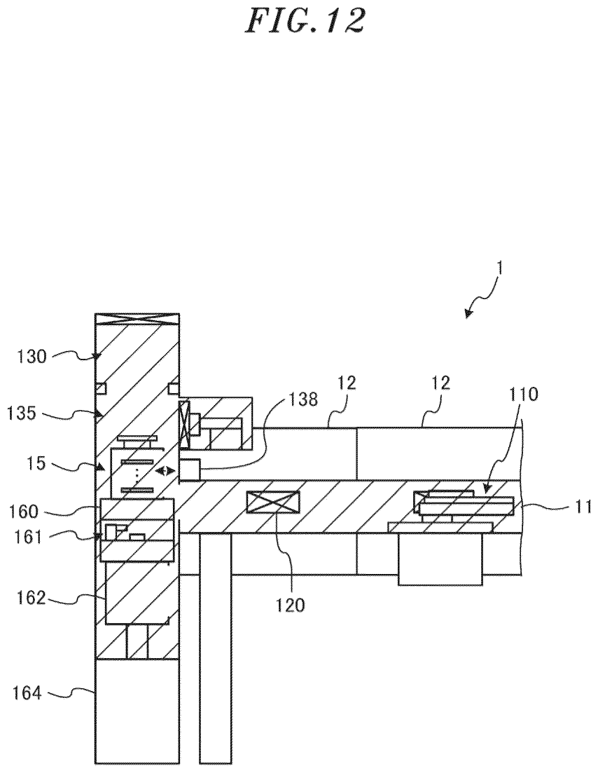

Next, a location of the substrate W within the container 15 is detected (S105). In step S105, for example, as illustrated in FIG. 12, when the container 15 passes through the first transfer chamber 135 near the sensor 138, the location of the substrate W accommodated in the container 15 is detected by the sensor 138.

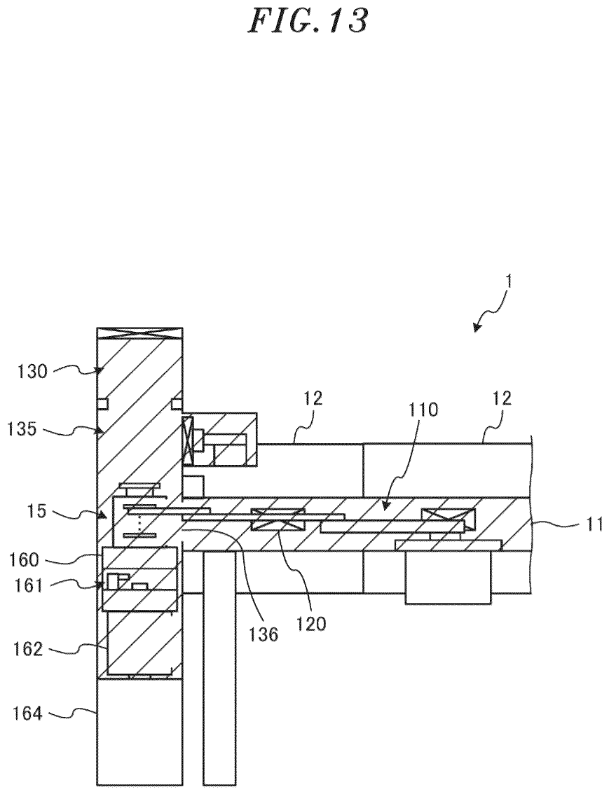

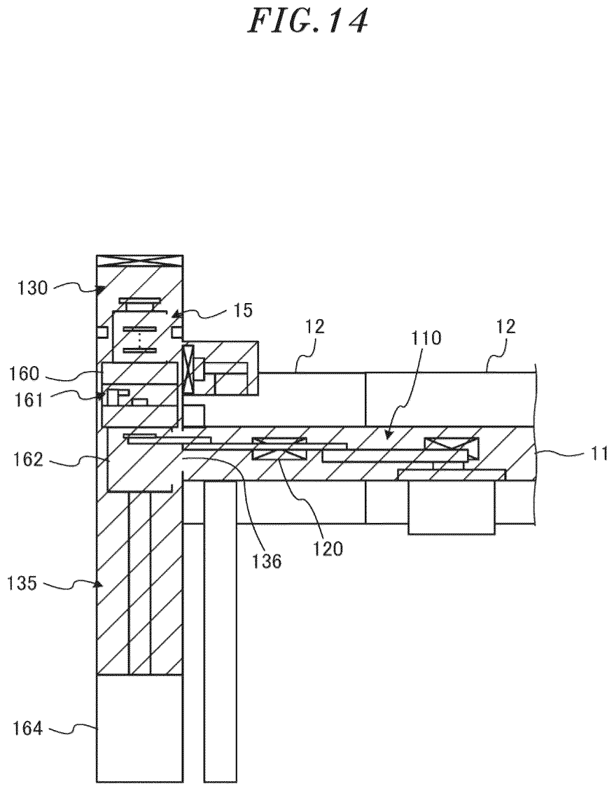

Next, the substrate W before processing in the container 15 is carried into the accommodation portion 162 (S106). Step S106 is an example of process d). In step S106, for example, as illustrated in FIG. 13, the substrate W in the container 15 is taken out by the transfer robot 110 in the VTM 11 through the opening 136. Then, the container 15, the stage 160, the aligner module 161, and the accommodation portion 162 are moved upward by the drive portion 164. In addition, for example, as illustrated in FIG. 14, the substrate W taken out from the container 15 is carried into the accommodation portion 162 by the transfer robot 110. In step S106, all the substrates W before processing in the container 15 are once carried into the accommodation portion 162.

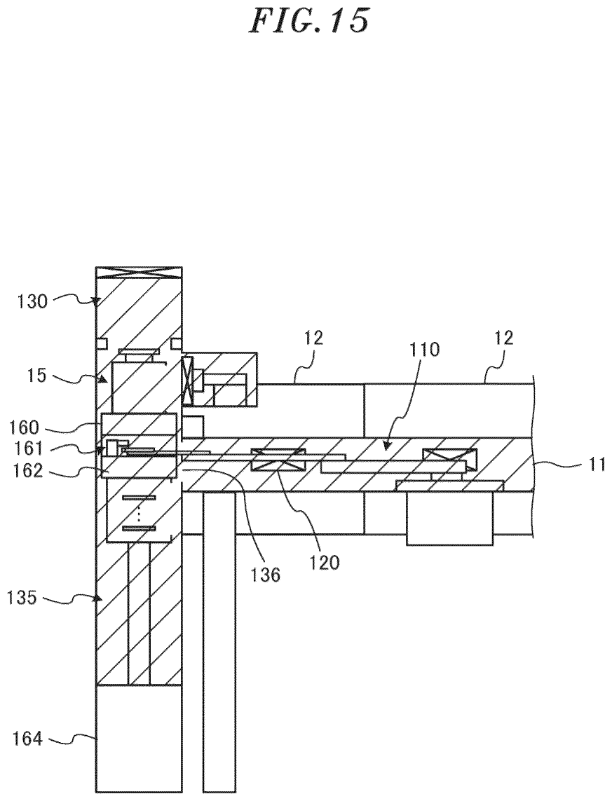

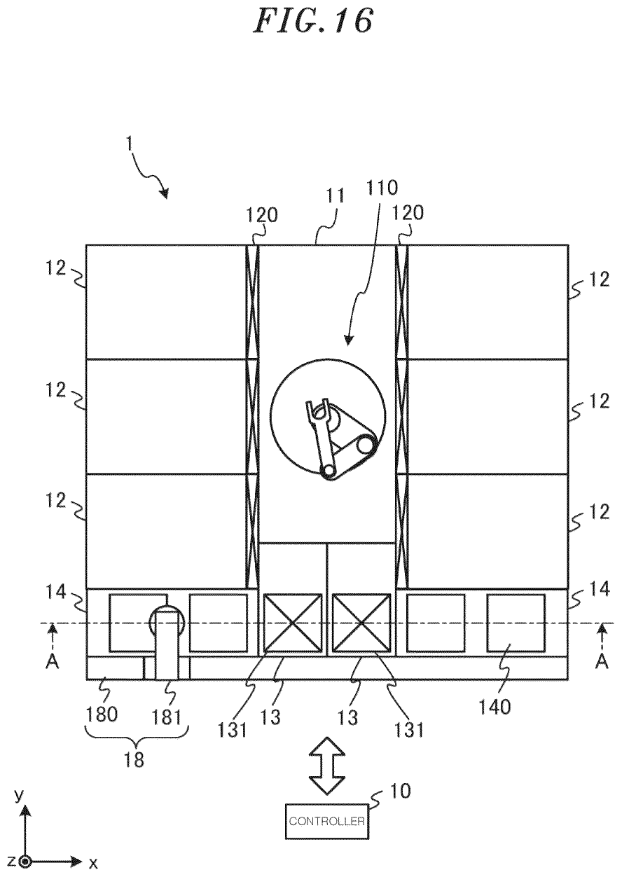

Next, the substrate W before processing is carried into the VTM 11 from the accommodation portion 162 (S107). Step S107 is an example of process e). In step S107, the substrate W is carried out from the accommodation portion 162 by the transfer robot 110, and the container 15, the stage 160, the aligner module 161, and the accommodation portion 162 are moved downward by the drive portion 164. Then, for example, as illustrated in FIG. 15, the substrate W taken out from the accommodation portion 162 is mounted on the aligner module 161. Then, the substrate W whose direction has been adjusted by the aligner module 161 is carried into the VTM 11 via the opening 136 by the transfer robot 110.

As such, the substrate W before processing is moved from the container 15 to the accommodation portion 162, the substrate W before processing is moved from the accommodation portion 162 to the aligner module 161, and the substrate W after processing is moved from the VTM 11 to the container 15 by the transfer robot 110 within the VTM 11. As a result, there is no need to separately dispose a transfer robot in the first transfer chamber 135 apart from the transfer robot 110 in the VTM 11, and the EFEM 13 may be downsized.

Next, processing of the substrate W is performed (S108). In step S108, the substrate W carried into the VTM 11 is carried into any of the PMs 12 by the transfer robot 110, and is processed by the PM 12.

Next, the substrate W after processing is transferred into the container 15 (S109). Step S109 is an example of process f). In step S109, the substrate W after processing is carried out from the PM 12 by the transfer robot 110. Then, the container 15, the stage 160, the aligner module 161, and the accommodation portion 162 are moved downward by the drive portion 164. In addition, for example, as illustrated in FIG. 13, the substrate W after processing is transferred into the container 15. In this embodiment, the substrate W before processing is transferred from the accommodation portion 162 to the PM 12, and the substrate W after processing is transferred into the container 15 without passing through the accommodation portion 162. As a result, the substrate W before processing and the substrate W after processing do not coexist in the container 15. Accordingly, it is possible to suppress so-called cross contamination in which particles and the like scattered from the substrate W after processing adhere to the substrate W before processing.

Next, when a predetermined number of the substrates W after processing are accommodated in the container 15, the cover 15 is attached to the container 150 (S110). In step S110, the drive portion 164 moves the container 15, the stage 160, the aligner module 161, and the accommodation portion 162 upward, and the cover attachment/detachment mechanism 137 attaches the cover 150 to the container 15.

Next, the container 15 is carried into the second transfer chamber 130 (S111). In step S111, the drive portion 164 moves the container 15, the stage 160, the aligner module 161, and the accommodation portion 162 moves upward. Then, the drive portion 175 locks the stage 160 by inserting the cylinder 176 into the base of the projection 1602. As a result, for example, as illustrated in FIG. 9, the space within the first transfer chamber 135 and the space within the second transfer chamber 130 are airtightly separated.

Next, an inert gas is supplied into the container 15 (S112). In step S112, the inert gas is supplied into the container 15 by opening the valve 173. As a result, for example, as illustrated in FIG. 8, the pressure inside the second transfer chamber 130 may be set to the same low pressure as the pressure inside the first transfer chamber 135 while maintaining the inside of the container 15 at atmospheric pressure.

Next, an inert gas is supplied into the second transfer chamber 130 (S113). In step S113, by opening the valve 171, the inert gas is supplied into the second transfer chamber 130, and the inside of the second transfer chamber 130 may be set to atmospheric pressure. As such, by setting the inside of the container 15 to atmospheric pressure before the inside of the second transfer chamber 130, it is possible to prevent particles and the like in the second transfer chamber 130 from entering the container 15.

Next, the container 15 is carried out from the second transfer chamber 130 (S114). In step S114, the gate valve 131 is opened, and for example, as illustrated in FIG. 5, the container 15 is carried out from the second transfer chamber 130 by a transfer mechanism such as the OHT 30. Then, the transfer method shown in this flowchart ends.

The first embodiment has been described above. As described above, the EFEM 13 in this embodiment includes the first transfer chamber 135, the second transfer chamber 130, and the stage 160. The first transfer chamber 135 is connected to the VTM 11 and is configured to be maintained at a low pressure lower than atmospheric pressure. The second transfer chamber 130 is provided in an upper portion of the first transfer chamber 135. Further, the second transfer chamber 130 may accommodate the container 15 that accommodates the plurality of substrates W, and is configured so that the internal pressure may be switched between atmospheric pressure and low pressure. The stage 160 is configured to partition the first transfer chamber 135 and the second transfer chamber 130. The first transfer chamber 135 includes the accommodation portion 162 configured to accommodate the substrate W before processing. The container 15 that accommodates the plurality of substrates W before processing is carried into the second transfer chamber 130, and the stage 160 is controlled to communicate the space within the first transfer chamber 135 and the space within the second transfer chamber 130 after the pressure in the second transfer chamber 130 is switched from the atmospheric pressure to the low pressure. Then, the plurality of substrates W before processing are transferred from the container 15 to the accommodation portion 162 in the first transfer chamber 135, and the plurality of substrates W before processing are transferred from the accommodation portion 162 to the VTM 11. Then, the substrate W after processing is transferred from the VTM 11 to the container 15 without passing through the accommodation portion 162. As a result, the installation area of the substrate processing system 1 may be reduced.

Further, in the first embodiment described above, the second transfer chamber 130 is provided in an upper portion of the first transfer chamber 135. In addition, the second transfer chamber 130 includes the drive portion 164 that is configured to move the container 15 up and down together with the stage 160. In addition, the container 15 that accommodates the plurality of substrates W before processing is accommodated in the second transfer chamber 130; after the pressure in the second transfer chamber 130 is switched from the atmospheric pressure to the low pressure, the stage 160 is controlled to communicate the space within the first transfer chamber 135 and the space within the second transfer chamber 130; and the container 15 is transferred to the first transfer chamber 135 together with the stage 160 by the drive portion 164. Then, the plurality of substrates W before processing is transferred from the container 15 to the accommodation portion 162 within the first transfer chamber 135. As a result, it is possible to avoid the coexistence of the substrate W before processing and the substrate W after processing in the container 15, and to suppress particles and the like scattered from the substrate W after processing from adhering to the substrate W before processing.

Further, in the first embodiment described above, the accommodation portion 162 is disposed below the stage 160, and the drive portion 164 is configured to integrally move the container 15, the stage 160, and the accommodation portion 162 up and down in the first transfer chamber 135. As a result, the drive portion 164 may be shared, and the number of parts may be reduced.

In addition, in the first embodiment described above, the transfer robot 110 in the VTM 11 is extendable into the first transfer chamber 135, and the plurality of substrates before processing may be transferred from the container 15 to the accommodation portion 162 by the transfer robot 110. As a result, there is no need to separately dispose a transfer robot in the first transfer chamber 135 apart from the transfer robot 110 in the VTM 11, and the EFEM 13 may be downsized.

Further, in the first embodiment described above, the cover attaching/detaching mechanism 137 and the sensor 138 are provided in the first transfer chamber 135. The cover attaching/detaching mechanism 137 is configured to attach/detach the cover 150 of the container 15. The sensor 138 is configured to detect the locations of the plurality of substrates W before processing accommodated in the container 15 when the container 15 from which the cover 150 has been detached by the cover attaching/detaching mechanism 137 passes in front of the sensor 138. As a result, the transfer robot 110 may transfer the substrate W before processing in the container 15.

Further, in the first embodiment described above, in the second transfer chamber 130, the container 15 is accommodated in the second transfer chamber 130, and the pressure in the second transfer chamber 130 is switched from the atmospheric pressure to the low pressure. Thereafter, the pressure in the container 15 is switched from the atmospheric pressure to the low pressure. As a result, particles and the like in the second transfer chamber 130 may be prevented from entering the container 15.

Further, in the first embodiment described above, while the pressure in the second transfer chamber 130 is switched from the atmospheric pressure to the low pressure in a state where the container 15 is accommodated in the second transfer chamber 130, an inert gas is supplied into the container 15. As a result, the pressure in the container 15 may be maintained at atmospheric pressure until the pressure in the second transfer chamber 130 is switched from the atmospheric pressure to the low pressure.

Further, the first embodiment described above is related to a transfer method in the EFEM 13, and includes process a), process b), process c), process d), process e), and process f). The EFEM 13 includes the first transfer chamber 135, the second transfer chamber 130, and the stage 160. The first transfer chamber 135 is connected to the VTM 11 and is configured to be maintained at a low pressure lower than atmospheric pressure. The second transfer chamber 130 is provided in an upper portion of the first transfer chamber 135. Further, the second transfer chamber 130 may accommodate the container 15 that accommodates the plurality of substrates W, and is configured so that the internal pressure may be switched between the atmospheric pressure and the low pressure. The stage 160 is configured to partition the first transfer chamber 135 and the second transfer chamber 130. The first transfer chamber 135 is provided with the accommodation portion 162 configured to accommodate the substrate W before processing. In process a), the container 15 accommodating the plurality of substrates W before processing is carried into the second transfer chamber 130. In process b), the pressure in the second transfer chamber 130 is switched from the atmospheric pressure to the low pressure. In process c), the stage 160 is controlled to communicate the space within the first transfer chamber 135 and the space within the second transfer chamber 130. In process d), the plurality of substrates W before processing are transferred from the container 15 to the accommodation portion 162 in the first transfer chamber 135. In process e), the plurality of substrates W before processing are transferred from the accommodation portion 162 into the VTM 11. In process f), the substrate W after processing is transferred from the VTM 11 into the container 15 without passing through the accommodation portion 162. As a result, the installation area of the substrate processing system 1 may be reduced.

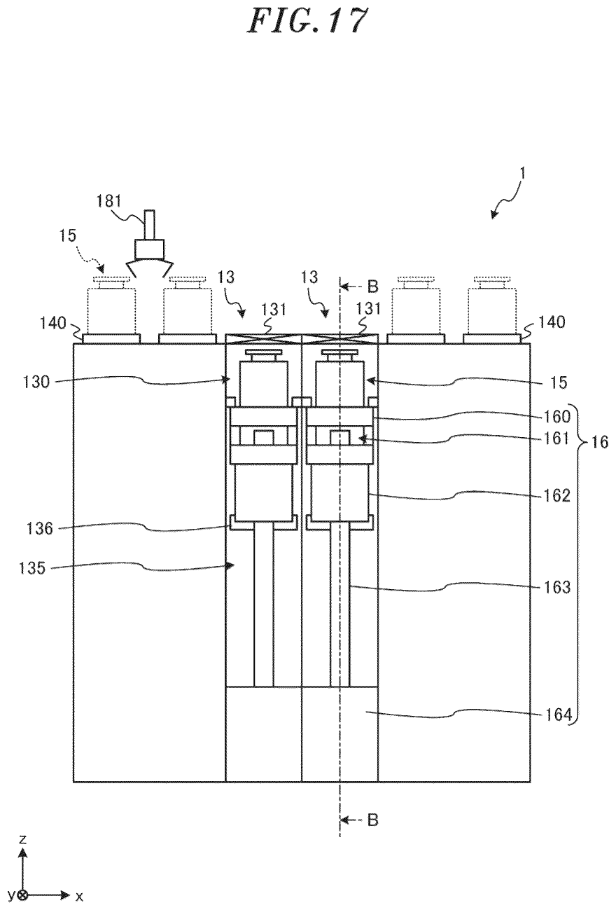

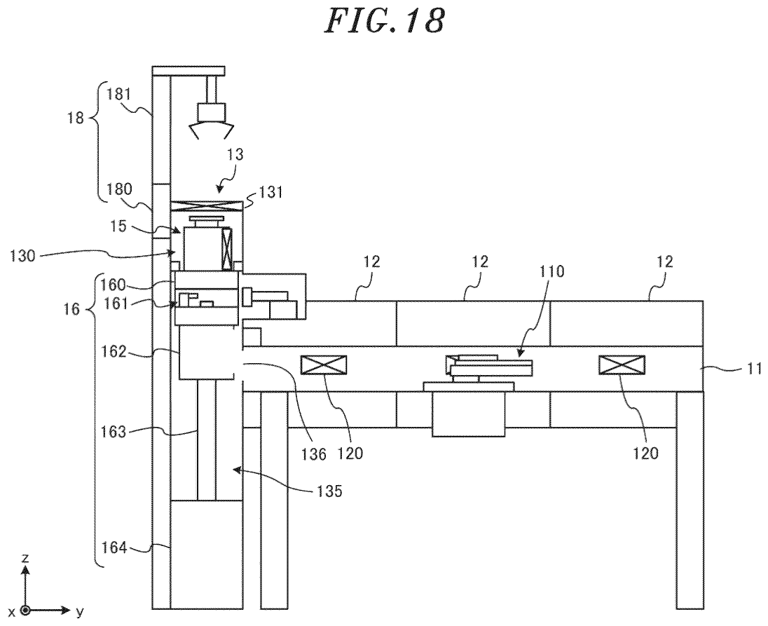

In addition, in the first embodiment described above, the container 15 is carried into the EFEM 13 by the OHT 30, but the described technology is not limited thereto. In another form, for example, as illustrated in FIGS. 16 to 18, a stage 140 may be provided on which the container 15 is temporarily mounted on the utility unit 14 by the OHT 30. FIG. 16 is a schematic plan view illustrating another example of the substrate processing system 1 in the first embodiment. FIG. 17 is a schematic cross-sectional view illustrating an example of the cross-section A-A of the substrate processing system 1 illustrated in FIG. 16. FIG. 18 is a schematic sectional view illustrating an example of the cross-section B-B of the substrate processing system 1 illustrated in FIG. 17. In addition, except for those explained below, in FIGS. 16 to 18, components given the same reference numerals as those in FIGS. 1 to 3 have the same or similar functions as the components in FIG. 1, and thus, descriptions thereof will be omitted.

In the examples shown in FIGS. 16 to 18, a plurality of stages 140 are provided for mounting the container 15 on the utility unit 14. Furthermore, a transfer mechanism 18 is provided on the sidewalls of the EFEM 13 and the utility unit 14. The transfer mechanism 18 includes a guide rail 180 and a crane 181. The crane 181 moves along the guide rail 180 and moves the container 15 between the stage 140 and the EFEM 13.

The container 15 accommodating the substrate W before processing is transferred by the OHT 30 and mounted on the stage 140. The crane 181 transfers the container 15 mounted on the stage 140 into the EFEM 13. Further, the crane 181 carries out the container 15 accommodating the substrate W after processing from the inside of the EFEM 13 and mounts the same on the stage 140. The container 15 mounted on the stage 140 is transferred by the OHT 30.

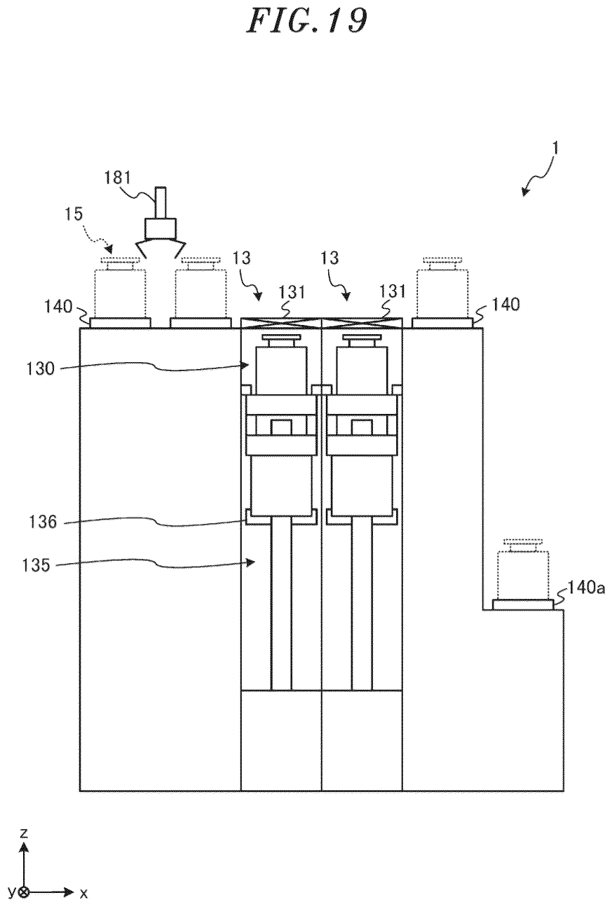

In addition, the transfer mechanism 18 may not be provided, and the movement of the container 15 between the stage 140 and the EFEM 13 may be performed by the OHT 30. Further, in the example of FIG. 17, the heights of the plurality of stages 140 are approximately the same, but the described technology is not limited thereto, and the heights of the plurality of stages 140 may be different. For example, some stages 140a among the plurality of stages 140 may be provided at a lower location than other stages 140, as illustrated in FIG. 19. As a result, the container 15 may be mounted on a stage 140a manually.

### Second Embodiment

### (Configuration of the Substrate Processing System 1)

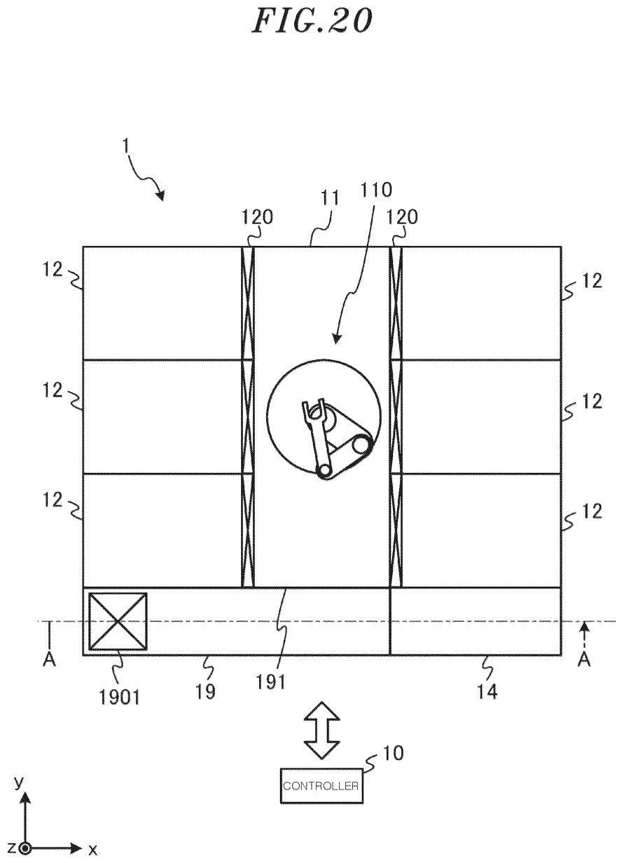

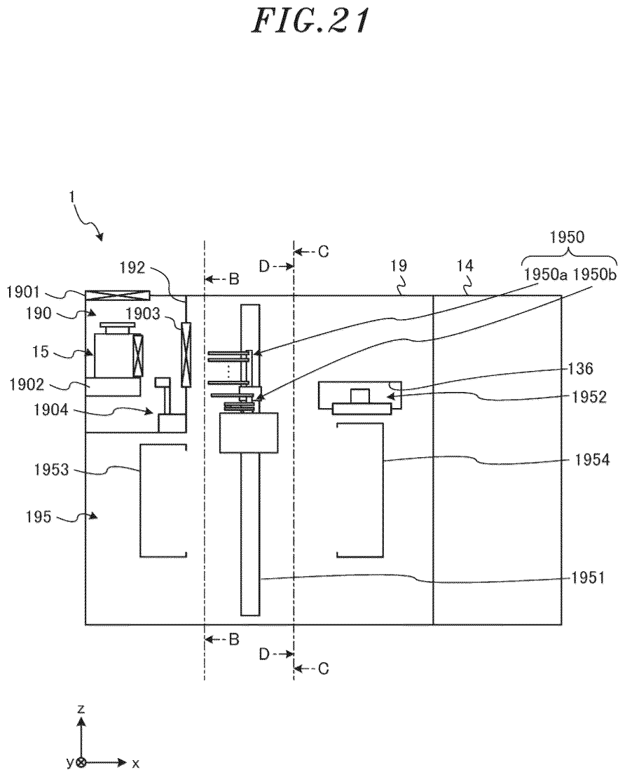

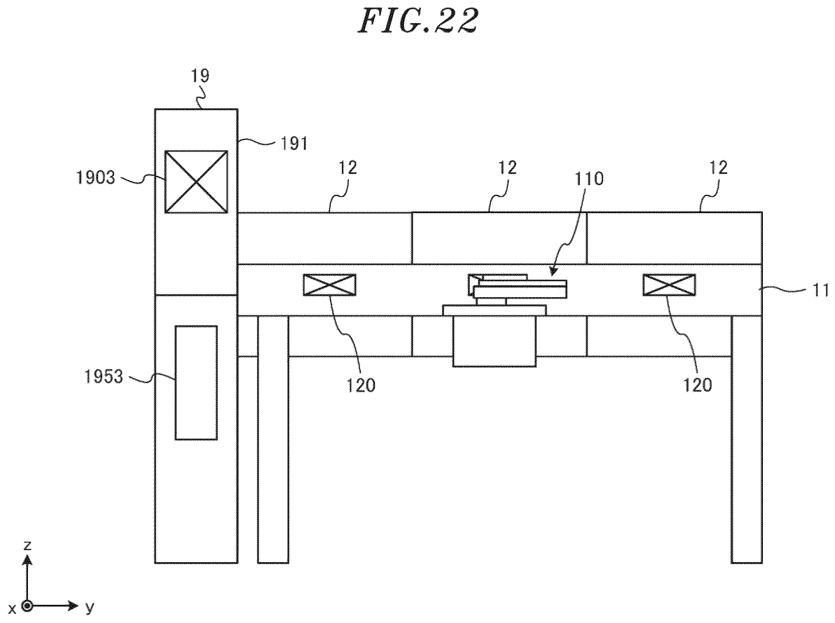

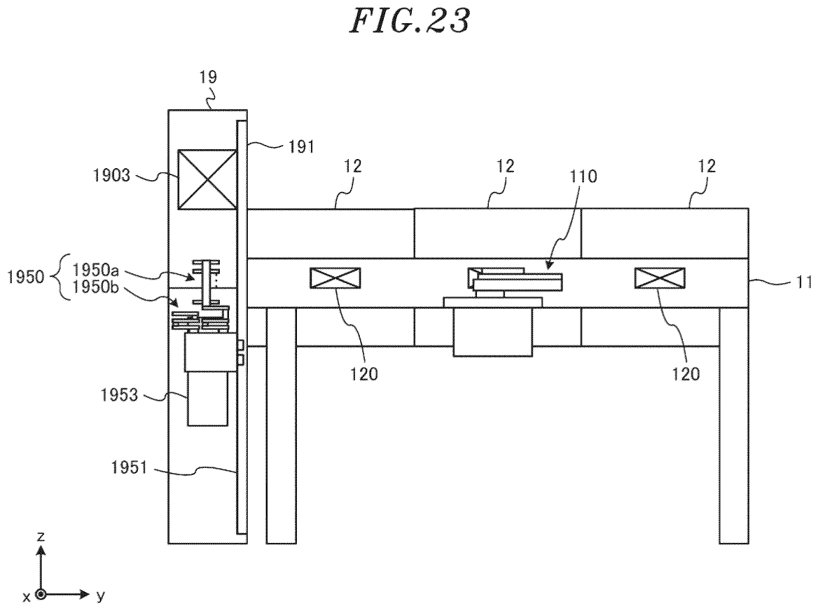

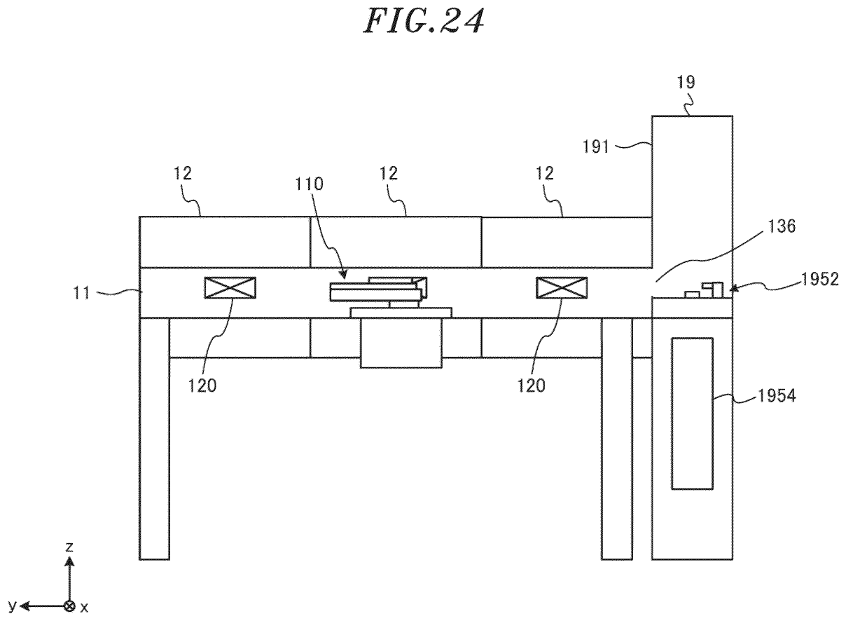

FIG. 20 is a schematic plan view illustrating an example of the substrate processing system 1 in a second embodiment. FIG. 21 is a schematic cross-sectional view illustrating an example of the cross-section A-A of the substrate processing system illustrated in FIG. 20. FIG. 22 is a schematic cross-sectional view illustrating an example of the cross-section B-B of the substrate processing system 1 illustrated in FIG. 21. FIG. 23 is a schematic cross-sectional view illustrating an example of the cross-section C-C of the substrate processing system illustrated in FIG. 21. FIG. 24 is a schematic cross-sectional view illustrating an example of the cross-section D-D of the substrate processing system 1 illustrated in FIG. 21. Further, in FIG. 21, illustration of the internal configuration of the utility unit 14 is omitted. In addition, except for those explained below, in FIGS. 20 to 24, components given the same reference numerals as those in FIGS. 1 to 3 have the same or similar functions as the components in FIGS. 1 to 3, and thus, descriptions thereof will be omitted.

For example, as illustrated in FIG. 20, the substrate processing system 1 of this embodiment includes the VTM 11, the plurality of PMs 12, and an EFEM 19. In the example of FIG. 20, the EFEM 19 is disposed adjacent to the VTM 11 in a y-axis direction of FIG. 20. Further, in the example of FIG. 20, the utility unit 14 is disposed adjacent to the EFEM 19 in an x-axis direction of FIG. 20.

For example, as illustrated in FIGS. 21 to 24, the EFEM 19 includes a first transfer chamber 195 and a second transfer chamber 190. A gate valve 1901 is provided in an upper portion of the second transfer chamber 190. The second transfer chamber 190 is provided on a second sidewall 192 other than the sidewall opposite to a first sidewall 191 to which the VTM 11 is connected in the first transfer chamber 195, and may accommodate the container 15. Further, the second transfer chamber 130 is configured to be able to switch the internal pressure between atmospheric pressure and a low pressure that is the same pressure as the pressure inside the first transfer chamber 135. A cover attaching/detaching mechanism 1904 for detaching and attaching the cover 150 of the container 15 is provided in the second transfer chamber 190. The space within the first transfer chamber 195 and the space within the second transfer chamber 190 are partitioned by a gate valve 1903.

The space within the first transfer chamber 195 communicates with the space within the VTM 11 through the opening 136, and is maintained at a low pressure lower than atmospheric pressure. Inside the first transfer chamber 195, a transfer robot 1950, a guide rail 1951, an aligner module 1952, an accommodation portion 1953, and an accommodation portion 1954 are provided.

The transfer robot 1950 moves within the first transfer chamber 195 along the guide rails 1951. The transfer robot 1950 includes a first arm 1950a having a plurality of forks and capable of transferring the plurality of substrates W en bloc, and a second arm 1950b having one fork and capable of transferring substrates W one by one. The aligner module 1952 adjusts a direction of substrate W. The accommodation portion 1953 and the accommodation portion 1954 hold the plurality of substrates W before processing.

### [Transfer Method]

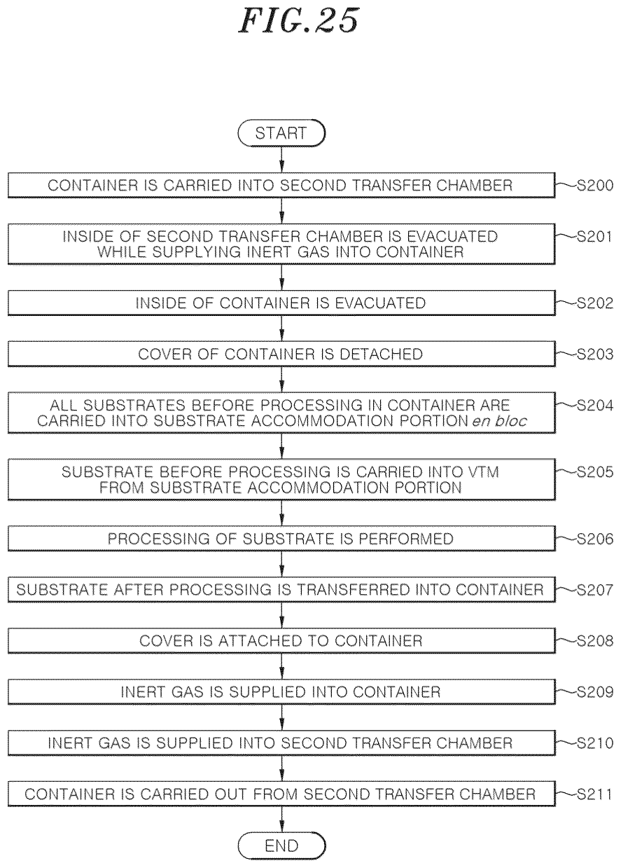

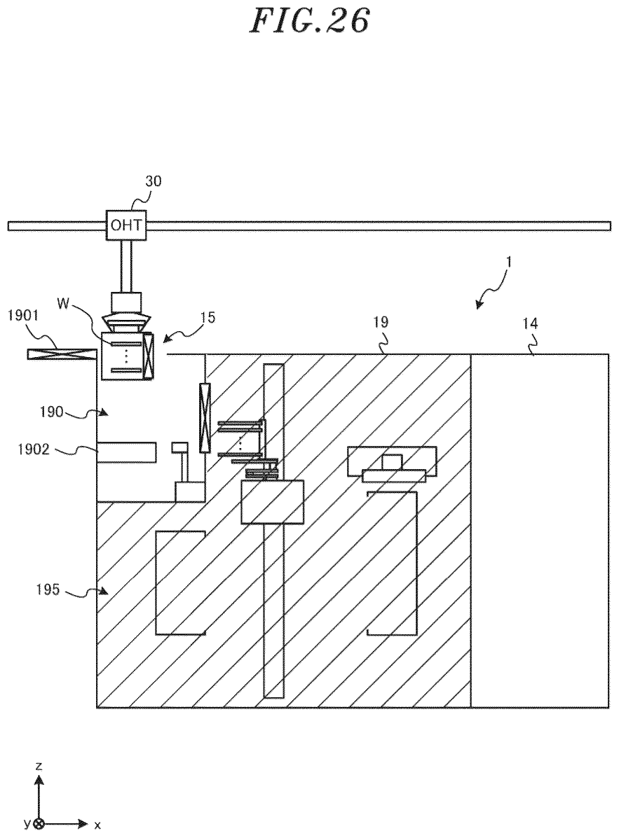

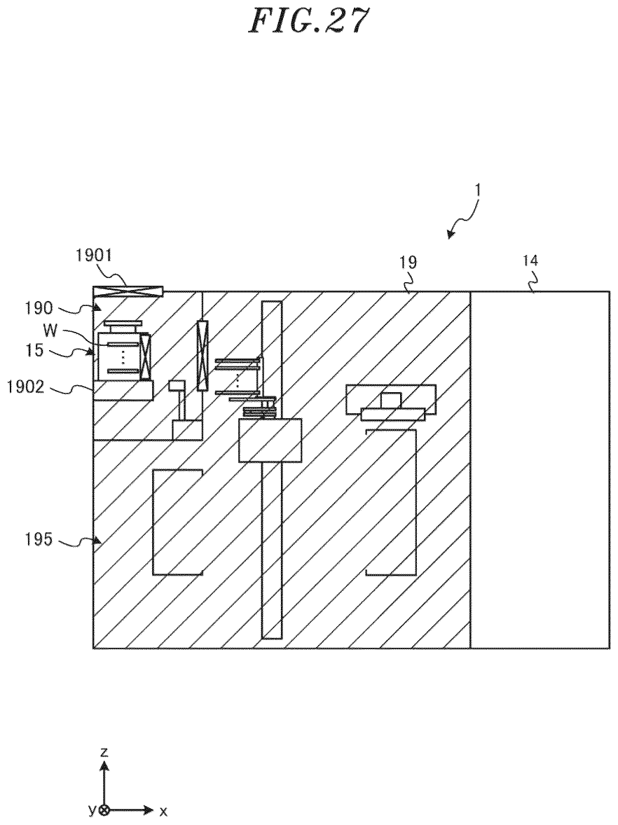

FIG. 25 is a flowchart illustrating an example of a transfer method of the substrate W in the second embodiment. Hereinafter, an example of the method for transferring the substrate W illustrated in FIG. 25 will be described with reference to FIGS. 26 to 35. In addition, in FIGS. 26 to 35, a low pressure space is hatched to distinguish between the atmospheric pressure space and the low pressure space.

First, the container 15 accommodating the plurality of substrates W before processing is carried into the second transfer chamber 190 (S200). In step S200, for example, as illustrated in FIG. 26, the gate valve 1901 is opened, and the container 15 accommodating the plurality of substrates W before processing is carried into the second transfer chamber 190 by the OHT 30. Thereafter, the OHT 30 rotates the container 15 to face the cover attaching/detaching mechanism 1904. Then, the container 15 is mounted on the stage 1902, and the gate valve 1901 is closed. In addition, the stage 1902 of this embodiment is provided with a connector for connecting a gas pipe, similar to the stage 160 of the first embodiment.

Next, the inside of the second transfer chamber 190 is evacuated while supplying an inert gas into the container 15 (S201). In step S201, the inert gas is supplied into the container 15 by opening a valve provided on a pipe for supplying the inert gas into the container 15. In addition, the gas in the second transfer chamber 190 is exhausted by opening a valve provided on a pipe for exhausting gas from the second transfer chamber 190. As a result, for example, as illustrated in FIG. 27, the pressure inside the second transfer chamber 190 may be set to the same low pressure as the pressure inside the first transfer chamber 195 while maintaining the inside of the container 15 at atmospheric pressure. As a result, it is possible to prevent particles and the like in the second transfer chamber 190 from entering the container 15.

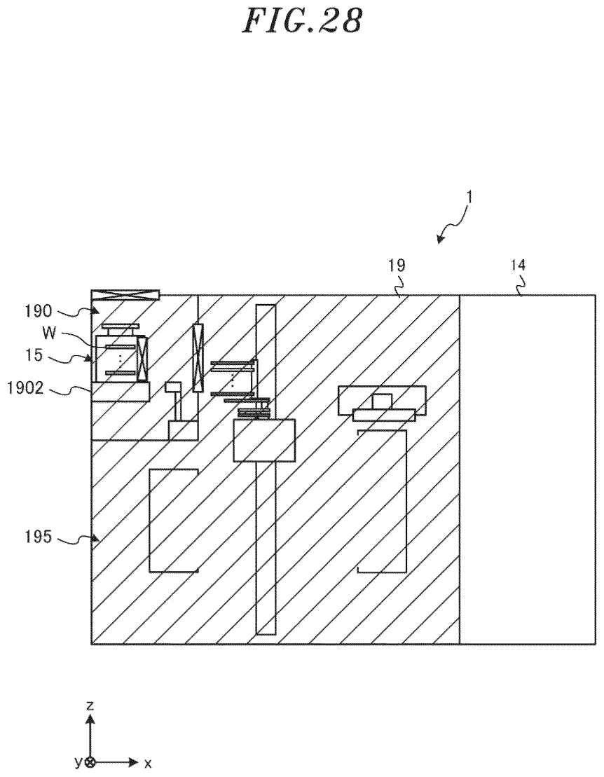

Next, the inside of the container 15 is evacuated (S202). In step S202, the gas in the container 15 is exhausted by closing a valve provided on a pipe for supplying the inert gas into the container 15 and opening a valve provided on a pipe for exhausting gas from the container 15. As a result, for example, shown in FIG. 28, the pressure in the container 15 and the pressure in the second transfer chamber 190 may be set to the same low pressure as the pressure in the first transfer chamber 195.

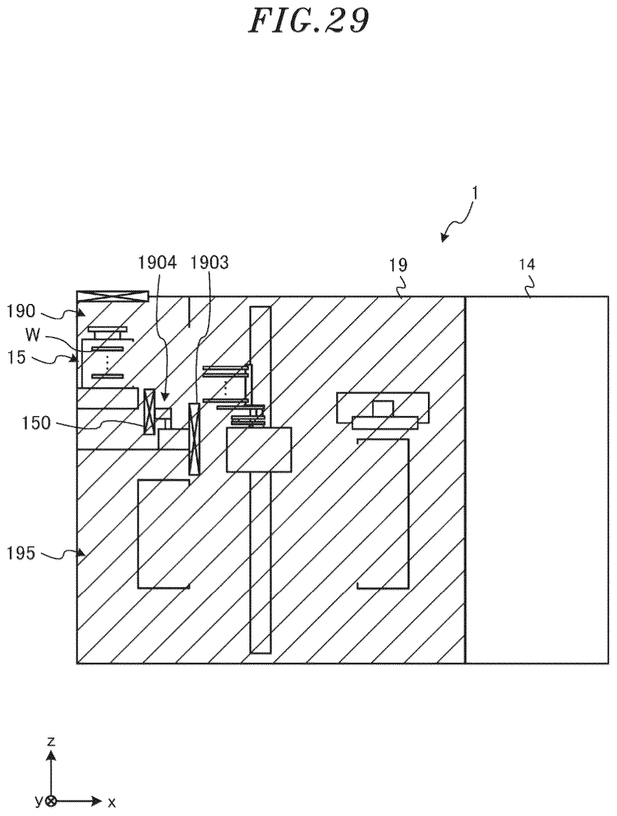

Next, the cover 150 of the container 15 is detached (S203). In step S203, for example, as illustrated in FIG. 29, the cover 150 of the container 15 is detached by the cover attachment/detachment mechanism 1904, and the gate valve 1903 is opened.

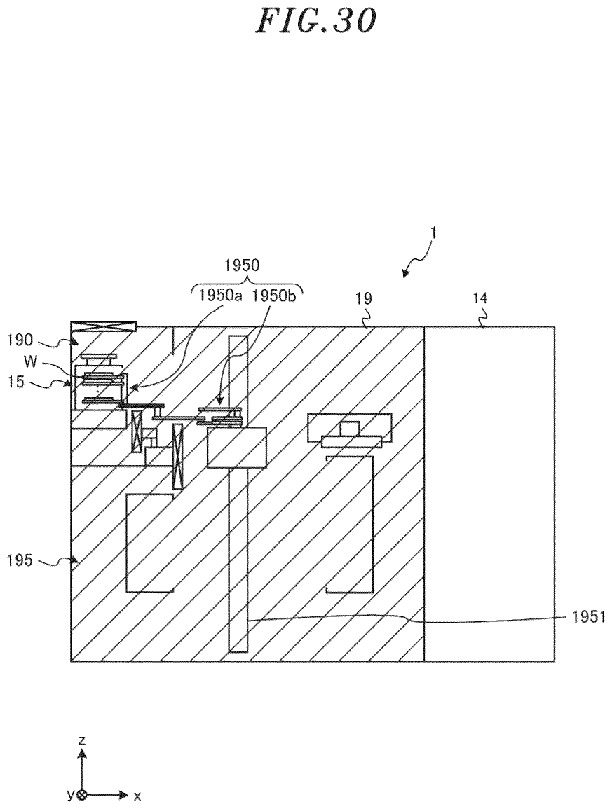

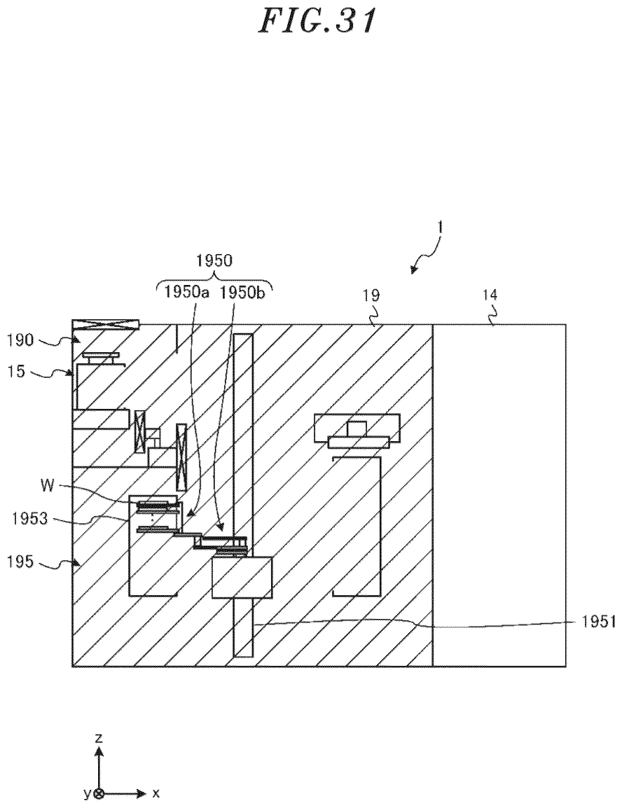

Next, all the substrates W before processing in the container 15 are carried out and carried into the accommodation portion 1953 or the accommodation portion 1954 en bloc (S204). In step S204, for example, as illustrated in FIG. 30, the first arm 1950a is inserted into the container 15, and all substrates W before processing in the container 15 are carried out by the first arm 1950a. Then, for example, as illustrated in FIG. 31, the transfer robot 1950 moves along the guide rail 1951, and the plurality of substrates W carried out from the container 15 are carried into the accommodation portion 1953.

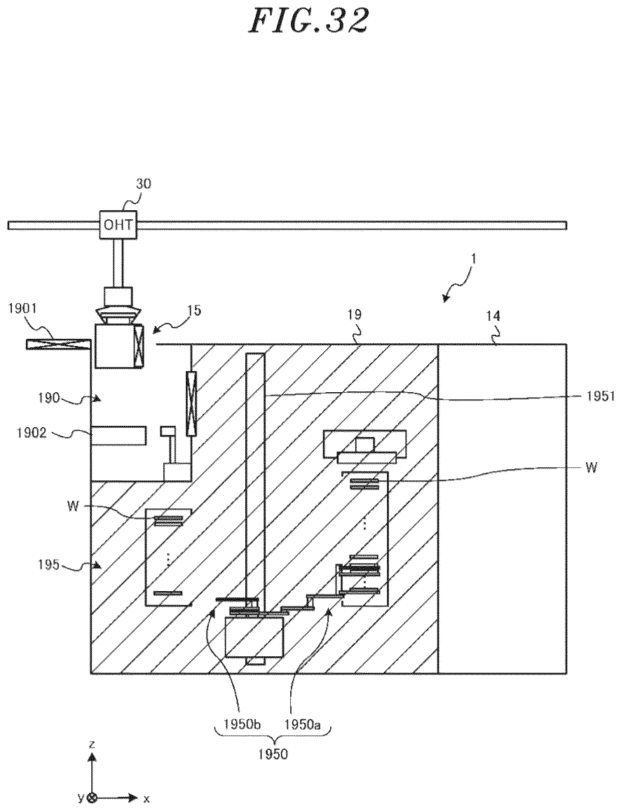

The cover 150 is attached to the container 15 from which all the substrates W have been carried out by the cover attaching/detaching mechanism 1904. Then, the pressure in the second transfer chamber 190 and the container 15 is returned to atmospheric pressure. For example, as illustrated in FIG. 32, the gate valve 1901 is opened, and the container 15 is carried out from the second transfer chamber 190 by the OHT 30. Then, another container 15 accommodating the substrate W before processing is carried into the second transfer chamber 190 by the OHT 30, and similar to the processing shown in steps S201 to S204, all the substrates W in the container 15 are carried into the accommodation portion 1953 or the accommodation portion 1954 en bloc. As a result, for example, as illustrated in FIG. 32, the plurality of substrates W before processing are accommodated in the accommodation portion 1953 and the accommodation portion 1954.

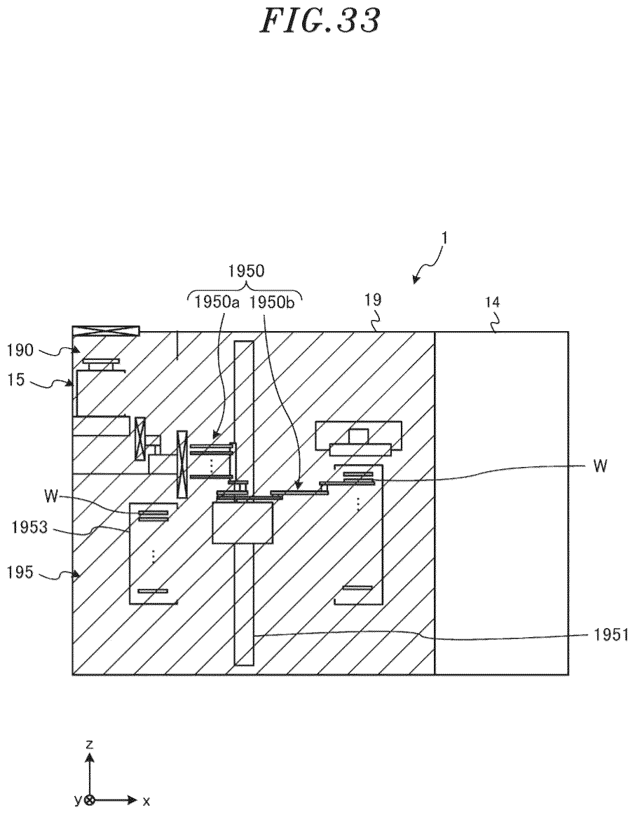

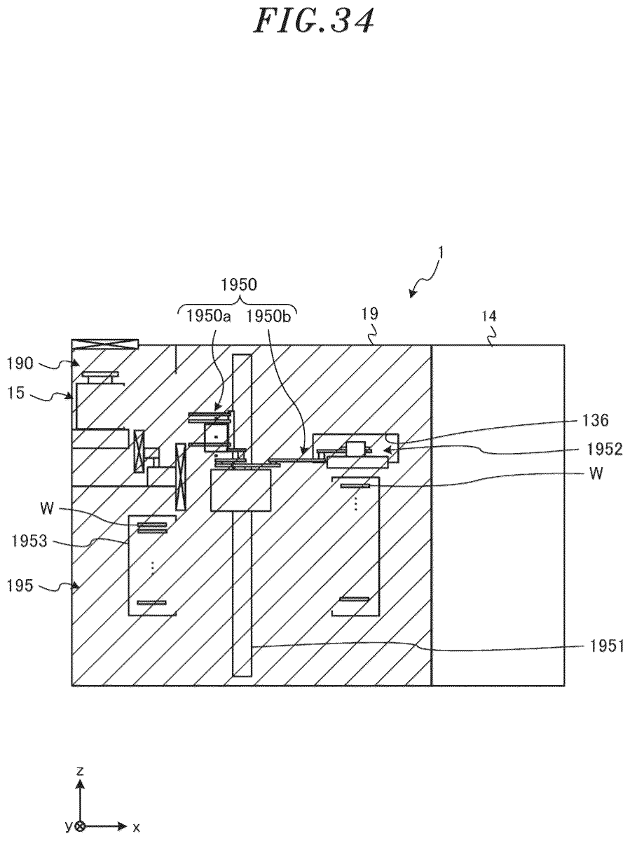

Next, the substrate W before processing is carried into the VTM 11 from the accommodation portion 1953 or the accommodation portion 1954 (S205). In step S205, for example, as illustrated in FIG. 33, one substrate W is carried out from the accommodation portion 1953 or the accommodation portion 1954 by the second arm 1950b. Then, for example, as illustrated in FIG. 34, the substrate W before processing is mounted on the aligner module 1952 by the second arm 1950b. The aligner module 1952 adjusts a direction of substrate W. The substrate W whose direction has been adjusted is carried into the VTM 11 via the opening 136 by the transfer robot 110 of the VTM 11.

Next, processing of the substrate W is performed (S206). In step S206, the substrate W carried into the VTM 11 is carried into any of the PMs 12 by the transfer robot 110, and is processed by the PM 12.

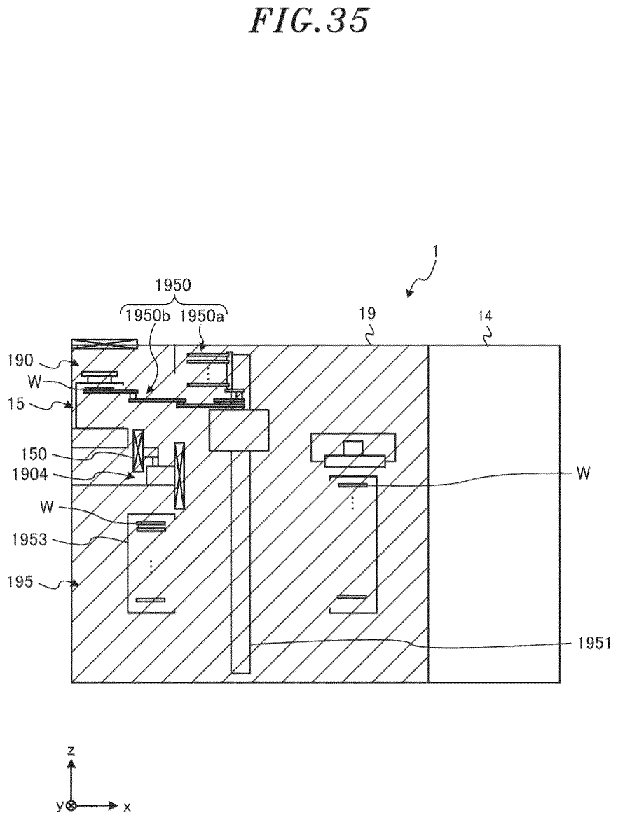

Next, the substrate W after processing is transferred into the container 15 (S207). In step S207, the substrate W after processing is carried out from the PM 12 by the transfer robot 110, and is mounted on the aligner module 1952 through the opening 136. The substrate W mounted on the aligner module 1952 is taken out by the second arm 1950b and carried into the container 15, as illustrated in FIG. 35, for example.

Next, when a predetermined number of the substrates W after processing are accommodated in the container 15, the cover 150 is attached to the container 15 (S208). In step S208, for example, as illustrated in FIG. 28, the gate valve 1903 is closed, and the cover 150 is attached to the container 15 by the cover attaching/detaching mechanism 1904.

Next, an inert gas is supplied into the container 15 (S209). In step S209, the inert gas is supplied into the container 15 by opening a valve provided on a pipe for supplying the inert gas into the container 15. As a result, for example, as illustrated in FIG. 27, the pressure inside the second transfer chamber 190 may be set to the same low pressure as the pressure inside the first transfer chamber 195 while maintaining the inside of the container 15 at atmospheric pressure. As a result, it is possible to prevent particles and the like in the second transfer chamber 190 from entering the container 15.

Next, an inert gas is supplied into the second transfer chamber 190 (S210). In step S210, the inert gas is supplied into the second transfer chamber 190 by opening a valve provided in a pipe for supplying the inert gas into the second transfer chamber 190.

Next, the container 15 is carried out from the second transfer chamber 190 (S211). In step S211, the gate valve 1901 is opened, and for example, as illustrated in FIG. 26, the container 15 is carried out from the second transfer chamber 190 by the OHT 30. Then, the transfer method shown in this flowchart ends.

The second embodiment has been described above. As described above, in this embodiment, the second transfer chamber 190 is provided on the second sidewall 192 other than the sidewall opposite to the first sidewall 191 to which the VTM 11 is connected in the first transfer chamber 195. In the first transfer chamber 195, there is provided the transfer robot 1950 which has the first arm 1950a provided with a plurality of forks configured to mount the substrate W thereon. The transfer robot 1950 transfers the plurality of substrates W before processing accommodated in the container 15 to the accommodation portion 1953 or the accommodation portion 1954 en bloc. As a result, the installation area of the substrate processing system 1 may be reduced.

Furthermore, in the second embodiment described above, the transfer robot 1950 further includes the second arm 1950b provided with one fork. The transfer robot 1950 transfers the substrate W before processing accommodated in the accommodation portion 1953 or the accommodation portion 1954 to the VTM 11 using the second arm 1950b.

### Other Embodiments

In addition, the technology described in the present disclosure is not limited to the embodiments described above, and many modifications can be made within the scope of the gist.

For example, in the first embodiment described above, although the moving mechanism 16 is provided with the aligner module 161 and the accommodation portion 162, the described technology is not limited thereto. In another form, the aligner module 161 and the accommodation portion 162 may be provided in the VTM 11.

Further, in the first embodiment described above, the movement of the substrate W before processing between the container 15 and the accommodation portion 162 is performed by the transfer robot 110 within the VTM 11, but the described technology is not limited thereto. As another form, a transfer robot having a plurality of forks and capable of transferring the plurality of substrates W en bloc may be provided in the first transfer chamber 135, and the transfer robot may transfer the substrate W before processing from the container 15 to the accommodation portion 162 en bloc. As a result, the time required to transfer the substrate W before processing from the container 15 to the accommodation portion 162 may be reduced.

Further, in the first embodiment described above, the substrate W is accommodated in the container 15, and the VTM 11 and the EFEM 13 transfer the substrate W, but the described technology is not limited thereto. In another form, the container 15 may accommodate consumables used in the PM 12, and the VTM 11 and EFEM 13 may transfer the consumables accommodated in the container 15. In this connection, the VTM 11 and the EFEM 13 may transfer the consumables before use to the accommodation portion 162, carry out the consumables after use from the PM 12 and accommodate the same in the container 15, and transfer the consumables before use into the PM 12. In addition, the VTM 11 and the EFEM 13 may transfer not only consumables before use but also consumables that have been used even once into the PM 12 via the accommodation portion 162. The consumables are an example of objects to be transferred.

In addition, in the second embodiment described above, the substrate W is accommodated in the container 15, and the VTM 11 and the EFEM 19 transfer the substrate W, but the described technology is not limited thereto. In another form, the container 15 may accommodate consumables used in the PM 12, and the VTM 11 and EFEM 19 may transfer the consumables accommodated in the container 15. In this connection, the VTM 11 and the EFEM 19 may transfer the consumables before use to the accommodation portion 1953 or the accommodation portion 1954, carry out the consumables after use from the PM 12 and accommodate the same in the container 15, and transfer the consumables before use into the PM 12. In addition, the VTM 11 and the EFEM 19 may transfer not only consumables before use but also consumables that have been used even once into the PM 12 via the accommodation portion 1953 or the accommodation portion 1954.

Further, in the first embodiment described above, only the substrate W before processing is accommodated in the accommodation portion 162, but the described technology is not limited thereto. As another form, two airtightly partitioned spaces may be provided in the accommodation portion 162, and the substrate W before processing may be accommodated in one space and the substrate W after processing may be accommodated in the other space. As a result, even during the waiting time until the container 15 is transferred by the OHT 30, the substrate W before processing may be carried out from one space in the accommodation portion 162, and the substrate W after processing may be carried into the other space in the accommodation portion 162.

Further, in the second embodiment described above, only the substrate W before processing is accommodated in the accommodation portion 1953 or the accommodation portion 1954, but the described technology is not limited thereto. As another form, the accommodation portion 1953 and the accommodation portion 1954 may be airtightly partitioned, and the substrate W before processing may be accommodated in one of the accommodation portion 1953 and the accommodation portion 1954 and the substrate W after processing may be accommodated in the other thereof. As a result, even during the waiting time until the container 15 is transferred by the OHT 30, the substrate W before processing may be carried out from one of the accommodation portion 1953 and the accommodation portion 1954, and the substrate W after processing may be carried into the other of the accommodation portion 1953 and the accommodation portion 1954.

In addition, also in the second embodiment described above, the plurality of stages 140 and the transfer mechanism 18 for mounting the container 15 on the utility unit 14 and the EFEM 19 may be provided, as in FIGS. 16 to 18. Further, the height of at least one stage 140 among the plurality of stages 140 on the utility unit 14 may be lower than the other stages 140, for example, as in FIG. 19.

Further, in the second embodiment described above, the substrate W before processing is transferred to the VTM 11 via the aligner module 1952, and the substrate W after processing is carried out to the container 15 via the aligner module 1952. However, the described technology is not limited thereto. In another form, the aligner module 1952 may be located remotely from the opening 136. Then, the substrate W before processing whose direction has been adjusted by the aligner module 1952 may be taken out from the aligner module 1952 by the second arm 1950b and delivered to the transfer robot 110 via the opening 136. Further, the substrate W after processing transferred by the transfer robot 110 may be delivered to the second arm 1950b without passing through the aligner module 1952, and may be carried into the container 15 by the second arm 1950b.

In addition, the presently described embodiments are considered in all respects to be illustrative and not restrictive. The aforementioned embodiments may be embodied in various forms. Further, the aforementioned embodiments may be omitted, replaced, or changed in various forms without departing from the scope of the appended claims and the gist thereof.

Further, regarding the above embodiment, the following additional notes are described.

### (Appendix 1)

A transfer module, comprising:
a first transfer chamber connected to a vacuum transfer module and configured to be maintained at a low pressure lower than atmospheric pressure;
a second transfer chamber provided on a second sidewall other than a sidewall opposite to a first sidewall to which the vacuum transfer module is connected in the first transfer chamber or in an upper portion of the first transfer chamber, the second transfer chamber capable of accommodating a container accommodating a plurality of objects to be transferred and being configured to be able to switch an internal pressure between the atmospheric pressure and the low pressure; and
an opening/closing door configured to partition the first transfer chamber and the second transfer chamber,
wherein the first transfer chamber has an accommodation portion configured to accommodate the object to be transferred, and
the container accommodating the plurality of objects to be transferred is carried into the second transfer chamber, the opening/closing door is controlled to communicate a space in the first transfer chamber and a space in the second transfer chamber after a pressure in the second transfer chamber is switched from the atmospheric pressure to the low pressure, the plurality of objects to be transferred are transferred from the container to the accommodation portion in the first transfer chamber, the object to be transferred is transferred from the accommodation portion into the vacuum transfer module, and the object to be transferred carried out from the vacuum transfer module is transferred into the container without passing through the accommodation portion.

### (Appendix 2)

The transfer module of appendix 1, wherein the second transfer chamber is provided in the upper portion of the first transfer chamber,
the first transfer chamber has a drive portion configured to move the container up and down together with the opening/closing door, and
the container accommodating the plurality of objects to be transferred is accommodated in the second transfer chamber, the opening/closing door is opened after the pressure in the second transfer chamber is switched between the atmospheric pressure and the low pressure, the container is transferred into the first transfer chamber together with the opening/closing door by the drive portion, and the plurality of objects to be transferred are transferred from the container to the accommodation portion in the first transfer chamber.

### (Appendix 3)

The transfer module of appendix 2, wherein the accommodation portion is disposed below the opening/closing door, and
the drive portion is configured to integrally move the container, the opening/closing door, and the accommodation portion up and down in the first transfer chamber.

### (Appendix 4)

The transfer module of appendix 2 or 3, wherein a transfer robot in the vacuum transfer module is extendable into the first transfer chamber, and
a transfer of the plurality of objects to be transferred from the container to the accommodation portion is performed by the transfer robot.

### (Appendix 5)

The transfer module of any one of appendices 2 to 4, wherein the transfer module is provided, in the first transfer chamber, with:
an attachment/detachment mechanism configured to attach and detach a cover of the container; and
a sensor configured to detect a location of the object to be transferred accommodated in the container when the container with cover the detached by the attachment/detachment mechanism passes in front of the sensor.

### (Appendix 6)

The transfer module of any one of appendices 1 to 5, further comprising:
a plurality of stages disposed adjacent to the second sidewall of the first transfer chamber, provided in an upper portion of an equipment accommodation portion in which electrical equipment used in the transfer module is accommodated, and configured to mount the container thereon; and
a transfer mechanism configured to transfer the container between the stage and the second transfer chamber.

### (Appendix 7)

The transfer module of appendix 6, wherein some stages among the plurality of stages are provided at a lower location than other stages.

### (Appendix 8)

The transfer module of appendix 1, wherein the second transfer chamber is provided on the second sidewall of the first transfer chamber,
a transfer robot having a first arm provided with a plurality of forks configured to mount the object to be transferred is provided in the first transfer chamber, and
the transfer robot transfers the plurality of objects to be transferred accommodated in the container en bloc to the accommodation portion.

### (Appendix 9)

The transfer module of appendix 8, wherein the transfer robot further comprises a second arm provided with one of the forks, and
the transfer robot uses the second arm to transfer the object to be transferred accommodated in the accommodation portion to the vacuum transfer module.

### (Appendix 10)

The transfer module of appendix 8 or 9, further comprising:
a plurality of stages provided in an upper portion of the first transfer chamber and configured to mount the container thereon; and
a transfer mechanism configured to transfer the container between the stage and the second transfer chamber.

### (Appendix 11)

The transfer module of any one of appendices 1 to 10, wherein, in the second transfer chamber, the container is accommodated in the second transfer chamber, and after the pressure in the second transfer chamber is switched from the atmospheric pressure to the low pressure, the pressure inside the container is able to be switched from the atmospheric pressure to the low pressure.

### (Appendix 12)

The transfer module of appendix 11, wherein an inert gas is supplied into the container while the pressure in the second transfer chamber is switched from the atmospheric pressure to the low pressure in a state where the container is accommodated in the second transfer chamber.

### (Appendix 13)

A transfer method performed in a transfer module, comprising:
a first transfer chamber connected to a vacuum transfer module and configured to be maintained at a low pressure lower than atmospheric pressure;
a second transfer chamber provided on a second sidewall other than a sidewall opposite to a first sidewall to which the vacuum transfer module is connected in the first transfer chamber or in an upper portion of the first transfer chamber, the second transfer chamber capable of accommodating a container accommodating a plurality of objects to be transferred and being configured to be able to switch an internal pressure between the atmospheric pressure and the low pressure; and
an opening/closing door configured to partition the first transfer chamber and the second transfer chamber,
wherein the first transfer chamber has an accommodation portion configured to accommodate the object to be transferred, the method comprising:
   a) a process of carrying the container accommodating the plurality of objects to be transferred into the second transfer chamber;
   b) a process of switching a pressure in the second transfer chamber from the atmospheric pressure to the low pressure;
   c) a process of controlling the opening/closing door to communicate a space within the first transfer chamber and a space within the second transfer chamber;
   d) a process of transferring the plurality of objects to be transferred from the container to the accommodation portion in the first transfer chamber;
   e) a process of transferring the object to be transferred from the accommodation portion into the vacuum transfer module; and
   f) a process of transferring the object to be transferred, which has been carried out from the vacuum transfer module, into the container without passing through the accommodation portion.

1. A transfer module, comprising:
a first transfer chamber connected to a vacuum transfer module and configured to be maintained at a low pressure lower than atmospheric pressure;
a second transfer chamber provided on a second sidewall other than a sidewall opposite to a first sidewall to which the vacuum transfer module is connected in the first transfer chamber or in an upper portion of the first transfer chamber, the second transfer chamber capable of accommodating a container accommodating a plurality of objects to be transferred and being configured to be able to switch an internal pressure between the atmospheric pressure and the low pressure; and
an opening/closing door configured to partition the first transfer chamber and the second transfer chamber,
wherein the first transfer chamber has an accommodation portion configured to accommodate the object to be transferred, and
the container accommodating the plurality of objects to be transferred is carried into the second transfer chamber, the opening/closing door is controlled to communicate a space in the first transfer chamber and a space in the second transfer chamber after a pressure in the second transfer chamber is switched from the atmospheric pressure to the low pressure, the plurality of objects to be transferred are transferred from the container to the accommodation portion in the first transfer chamber, the object to be transferred is transferred from the accommodation portion into the vacuum transfer module, and the object to be transferred carried out from the vacuum transfer module is transferred into the container without passing through the accommodation portion.

2. The transfer module of claim 1, wherein the second transfer chamber is provided in the upper portion of the first transfer chamber,
the first transfer chamber has a drive portion configured to move the container up and down together with the opening/closing door, and
the container accommodating the plurality of objects to be transferred is accommodated in the second transfer chamber, the opening/closing door is opened after the pressure in the second transfer chamber is switched between the atmospheric pressure and the low pressure, the container is transferred into the first transfer chamber together with the opening/closing door by the drive portion, and the plurality of objects to be transferred are transferred from the container to the accommodation portion in the first transfer chamber.

3. The transfer module of claim 2, wherein the accommodation portion is disposed below the opening/closing door, and
the drive portion is configured to integrally move the container, the opening/closing door, and the accommodation portion up and down in the first transfer chamber.

4. The transfer module of claim 2, wherein a transfer robot in the vacuum transfer module is extendable into the first transfer chamber, and
a transfer of the plurality of objects to be transferred from the container to the accommodation portion is performed by the transfer robot.

5. The transfer module of claim 3, wherein a transfer robot in the vacuum transfer module is extendable into the first transfer chamber, and
a transfer of the plurality of objects to be transferred from the container to the accommodation portion is performed by the transfer robot.

6. The transfer module of claim 2, wherein the transfer module is provided, in the first transfer chamber, with:
an attachment/detachment mechanism configured to attach and detach a cover of the container; and
a sensor configured to detect a location of the object to be transferred accommodated in the container when the container with the cover detached by the attachment/detachment mechanism passes in front of the sensor.

7. The transfer module of claim 1, further comprising:
a plurality of stages disposed adjacent to the second sidewall of the first transfer chamber, provided in an upper portion of an equipment accommodation portion in which electrical equipment used in the transfer module is accommodated, and configured to mount the container thereon; and
a transfer mechanism configured to transfer the container between the stage and the second transfer chamber.

8. The transfer module of claim 7, wherein some stages among the plurality of stages are provided at a lower location than other stages.

9. The transfer module of claim 1, wherein the second transfer chamber is provided on the second sidewall of the first transfer chamber,
a transfer robot having a first arm provided with a plurality of forks configured to mount the object to be transferred is provided in the first transfer chamber, and
the transfer robot transfers the plurality of objects to be transferred accommodated in the container en bloc to the accommodation portion.

10. The transfer module of claim 9, wherein the transfer robot further comprises a second arm provided with one of the forks, and
the transfer robot uses the second arm to transfer the object to be transferred accommodated in the accommodation portion to the vacuum transfer module.

11. The transfer module of claim 9, further comprising:
a plurality of stages provided in an upper portion of the first transfer chamber and configured to mount the container thereon; and
a transfer mechanism configured to transfer the container between the stage and the second transfer chamber.

12. The transfer module of claim 10, further comprising:
a plurality of stages provided in an upper portion of the first transfer chamber and configured to mount the container thereon; and
a transfer mechanism configured to transfer the container between the stage and the second transfer chamber.

13. The transfer module of claim 1, wherein, in the second transfer chamber, the container is accommodated in the second transfer chamber, and after the pressure in the second transfer chamber is switched from the atmospheric pressure to the low pressure, the pressure inside the container is able to be switched from the atmospheric pressure to the low pressure.

14. The transfer module of claim 13, wherein an inert gas is supplied into the container while the pressure in the second transfer chamber is switched from the atmospheric pressure to the low pressure in a state where the container is accommodated in the second transfer chamber.

15. A transfer method performed in a transfer module, comprising:
a first transfer chamber connected to a vacuum transfer module and configured to be maintained at a low pressure lower than atmospheric pressure;
a second transfer chamber provided on a second sidewall other than a sidewall opposite to a first sidewall to which the vacuum transfer module is connected in the first transfer chamber or in an upper portion of the first transfer chamber, the second transfer chamber capable of accommodating a container accommodating a plurality of objects to be transferred and being configured to be able to switch an internal pressure between the atmospheric pressure and the low pressure; and
an opening/closing door configured to partition the first transfer chamber and the second transfer chamber,
wherein the first transfer chamber has an accommodation portion configured to accommodate the object to be transferred, the method comprising:
a) a process of carrying the container accommodating the plurality of objects to be transferred into the second transfer chamber;
b) a process of switching a pressure in the second transfer chamber from the atmospheric pressure to the low pressure;
c) a process of controlling the opening/closing door to communicate a space within the first transfer chamber and a space within the second transfer chamber;
d) a process of transferring the plurality of objects to be transferred from the container to the accommodation portion in the first transfer chamber;
e) a process of transferring the object to be transferred from the accommodation portion into the vacuum transfer module; and
f) a process of transferring the object to be transferred, which has been carried out from the vacuum transfer module, into the container without passing through the accommodation portion.
